(19) United States
(12) Patent Application Publication
(10) Pub. No.: US 2025/0016506 A1
(43) Pub. Date: Jan. 9, 2025

(54) VIBRATION APPARATUS AND APPARATUS INCLUDING THE SAME

(71) Applicant: LG Display Co., Ltd., Seoul (KR)

(72) Inventors: YoungWook HA, Paju-si (KR); Chiwan KIM, Paju-si (KR); Yong-Su HAM, Paju-si (KR)

(73) Assignee: LG Display Co., Ltd., Seoul (KR)

(21) Appl. No.: 18/750,118

(22) Filed: Jun. 21, 2024

(30) Foreign Application Priority Data
Jul. 6, 2023 (KR) 10-2023-0087655

(51) Int. Cl. H04R 17/00; H04R 1/02; H04R 1/28; H04R 7/06

(52) U.S. Cl. CPC H04R 17/00; H04R 1/023; H04R 1/2834; H04R 7/06

(57) ABSTRACT

A vibration apparatus may include a vibration generating part including a plurality of vibration parts and a connection layer between the plurality of vibration parts, and the connection layer may include a glass frit.

### CROSS-REFERENCE TO RELATED APPLICATIONS

This application claims the benefit of and priority to Korean Patent Application No. 10-2023-0087655 filed on Jul. 6, 2023, the entirety of which is incorporated herein by reference for all purposes as if fully set forth herein.

### BACKGROUND

### 1. Technical Field

The present disclosure relates to a vibration apparatus and an apparatus including the same.

### 2. Discussion of the Related Art

Recently, the demands for slimmer and thinner electronic devices are increasing. In speakers applied to electronic devices, piezoelectric devices capable of being implemented with a thin thickness are attracting much attention instead of voice coils, based on the demands for slimmer and thinner devices.

Speakers or vibration apparatuses, to which a piezoelectric device is applied, may be driven or vibrated by a driving power or a driving signal supplied through a signal cable.

The description of the related art should not be assumed to be prior art merely because it is mentioned in or associated with this section. The description of the related art includes information that describes one or more aspects of the subject technology, and the description in this section does not limit the invention.

### SUMMARY

The inventors have performed extensive research and experiments for implementing a vibration apparatus where a manufacturing process and a structure of the vibration apparatus are simplified. The inventors have invented a vibration apparatus having a new structure and an apparatus including the vibration apparatus, in which a manufacturing process and a structure of the vibration apparatus are simplified, based on the extensive research and experiments.

One or more aspects of the present disclosure are directed to providing a vibration apparatus and an apparatus including the same, in which a structure thereof and a manufacturing process are simplified.

One or more aspects of the present disclosure are directed to providing a vibration apparatus and an apparatus including the same, in which an occurrence of cracks in the vibrating device may be prevented.

One or more aspects of the present disclosure are directed to providing a vibration apparatus and an apparatus including the same, in which a weight and a thickness may be reduced.

One or more aspects of the present disclosure are directed to providing a vibration apparatus and an apparatus including the same, which may improve a sound pressure level characteristic of a sound.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

A vibration apparatus according to an aspect of the present disclosure may include a vibration generating part including a plurality of vibration parts and a connection layer between the plurality of vibration parts, and the connection layer may include a glass frit.

An apparatus according to an aspect of the present disclosure may include a passive vibration member and a vibration generating apparatus which is connected to the passive vibration member and vibrates the passive vibration member. The vibration generating apparatus may include a vibration generating part including a plurality of vibration parts and a connection layer between the plurality of vibration parts, and the connection layer may include a glass frit.

According to an aspect of the present disclosure, a vibration apparatus capable of simplifying a structure and a manufacturing process and an apparatus including the same may be provided.

According to an aspect of the present disclosure, since the thickness of the vibration apparatus may be reduced to reduce weight, it is possible to implement a lightweight vibration apparatus.

According to an aspect of the present disclosure, the occurrence of a defect such as a crack may be prevented in a vibration apparatus, and thus, a yield rate may be enhanced, thereby decreasing production energy to implement process optimization.

According to an aspect of the present disclosure, process optimization through energy-saving production may be achieved by simplifying the manufacturing process.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain the principle of the disclosure.

FIG. 1 illustrates a vibration apparatus according to an aspect of the present disclosure.

FIG. 2 is an exploded perspective view illustrating a connection structure between a vibration generating part and a signal cable illustrated in FIG. 1 according to an aspect of the present disclosure.

FIG. 3 is a cross-sectional view taken along line A-A′ illustrated in FIG. 1 according to an aspect of the present disclosure.

FIG. 4 is a cross-sectional view taken along line B-B′ illustrated in FIG. 1 according to an aspect of the present disclosure.

FIG. 5 is a cross-sectional view taken along line C-C′ illustrated in FIG. 1 according to an aspect of the present disclosure.

FIGS. 6A to 6E illustrate a method of manufacturing a vibration apparatus according to an aspect of the present disclosure.

FIGS. 7A and 7B illustrate a cross-sectional surface image and a surface image of an electrode layer according to an experiment example 1.

FIGS. 8A to 8C illustrate a surface image of a connection layer according to an aspect of the present disclosure.

FIGS. 9A to 9C illustrate a cross-sectional surface image of each of a vibration layer, an electrode layer, and a connection layer according to an aspect of the present disclosure.

FIGS. 10A and 10B illustrate a cross-sectional surface image of a vibration generating part according to an aspect of the present disclosure.

FIG. 11 illustrate a cross-sectional surface image of an electrode layer according to an experiment example 2.

FIGS. 12 and 13 are diagrams for describing a cross-sectional surface of a vibration part based on a content of glass frit according to an aspect of the present disclosure;

FIG. 14 is a graph showing a sound pressure level characteristic according to an aspect of the present disclosure and the experiment example 2;

FIG. 15 illustrate an apparatus according to an aspect of the present disclosure.

FIG. 16 is a cross-sectional view taken along line D-D′ illustrated in FIG. 15 according to an aspect of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to aspects of the present disclosure, examples of which may be illustrated in the accompanying drawings. In the following description, when a detailed description of well-known methods, functions or configurations may unnecessarily obscure aspects of the present disclosure, the detailed description thereof may be omitted for brevity. The progression of processing steps and/or operations described is an example; however, the sequence of steps and/or operations is not limited to that set forth herein and may be changed, with the exception of steps and/or operations necessarily occurring in a particular order.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the aspects described with reference to the accompanying drawings. The present disclosure may, however, be embodied in different forms and should not be construed as limited to the aspects set forth herein. Rather, these aspects are examples and are provided so that this disclosure may be thorough and complete to assist those skilled in the art to understand the inventive concepts without limiting the protected scope of the present disclosure.

The shapes, sizes, areas, widths, heights, thicknesses, ratios, angles, numbers, the number of elements, and the like disclosed in the drawings for describing aspects of the present disclosure are merely examples, and thus, the present disclosure is not limited to the illustrated details. When the term “comprise,” “have,” “include,” “contain,” “constitute,” “made of,” “formed of,” “composed of,” or the like is used, one or more elements (e.g., layers, films, regions, components, sections, members, parts, regions, areas, portions, steps, operations, and/or the like) may be added unless a term such as “only” or the like is used. The terms used in the present disclosure are merely used to describe particular aspects, and are not intended to limit the scope of the present disclosure. The terms used herein are merely used to describe example aspects, and are not intended to limit the scope of the present disclosure. The terms of a singular form may include plural forms unless the context clearly indicates otherwise. The word “exemplary” is used to mean serving as an example or illustration. An aspect may be one or more example aspects. Aspects are example aspects. Any implementation described herein as an “example” or “aspect” is not necessarily to be construed as preferred or advantageous over other implementations.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompass all the meanings of the term “may.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, when a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” or the like may be used herein to describe various elements (e.g., layers, films, regions, components, sections, members, parts, regions, areas, portions, steps, operations, and/or the like), these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure. The terms “first,” “second,” and the like may be used to distinguish components from each other, but the functions or structures of the components are not limited by ordinal numbers or component names in front of the components.

In describing elements of the present disclosure, the terms “first,” “second,” “A,” “B,” “(a),” “(b),” or the like may be used. These terms are intended to identify the corresponding element(s) from the other element(s), and these terms are not used to define the essence, basis, order, or number of the elements.

For the expression that an element (e.g., layer, film, region, component, section, or the like) is “connected,” “coupled,” “attached,” “adhered,” or the like to another element, the element may not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element may not only directly contact, overlap, or the like with the another element, but also indirectly contact, overlap, or the like with another element with one or more intervening elements disposed or interposed between the elements or layers, unless otherwise specified.

The terms such as a “line” or “direction” should not be interpreted only based on a geometrical relationship in which the respective lines or directions are parallel or perpendicular to each other, and may be meant as lines or directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item,” may represent (i) a combination of items provided one or more of the first item, the second item, and the third item and (ii) only one of the first item, the second item, and the third item.

The expression of a first element, a second elements “and/or” a third element should be understood to encompass one of the first, second, and third elements, one of the first, second, and third elements, as well as any or all combinations of the first, second and third elements. By way of example, A, B and/or C encompass only A; only B; only C; any of A, B, and C (e.g., A, B, or C; some combination of A, B, and C (e.g., A and B; A and C; or B and C); and all of A, B, and C. Furthermore, an expression “A/B” may be understood as A and/or B. For example, an expression “A/B” can refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element (e.g., layer, film, region, component, sections, or the like) is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

Features of various aspects of the present disclosure may be partially or entirely coupled to or combined with each other, may be technically associated with each other, or may be operated, linked or driven together in various ways. Aspects of the present disclosure may be implemented or carried out independently from each other, or may be implemented or carried out together in a co-dependent or related relationship. In one or more aspects, the components of each apparatus according to various aspects of the present disclosure are operatively coupled and configured.

Unless otherwise defined, the terms (including technical and scientific terms) used herein have the same meaning as commonly understood by one of ordinary skill in the art to which example aspects belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field. However, there may be other terms than the terms depending on the development and/or change of technology, convention, preference of technicians, etc. Therefore, the terms used herein should not be understood as limiting technical ideas, but should be understood as examples of the terms for illustrating embodiments.

Further, in a specific case, a term may be arbitrarily selected by the applicant, and in this case, the detailed meaning thereof is described herein. Therefore, the terms used herein should be understood based on not only simply the name of the terms, but also the meaning of the terms and the contents thereof.

“X-axis direction,” “Y-axis direction” and “Z-axis direction” should not be construed by a geometric relation only of a mutual vertical relation and may have broader directionality within the range that elements of the present disclosure may act functionally.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

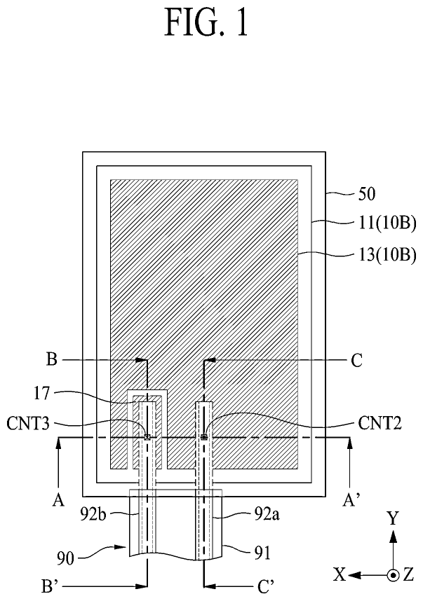

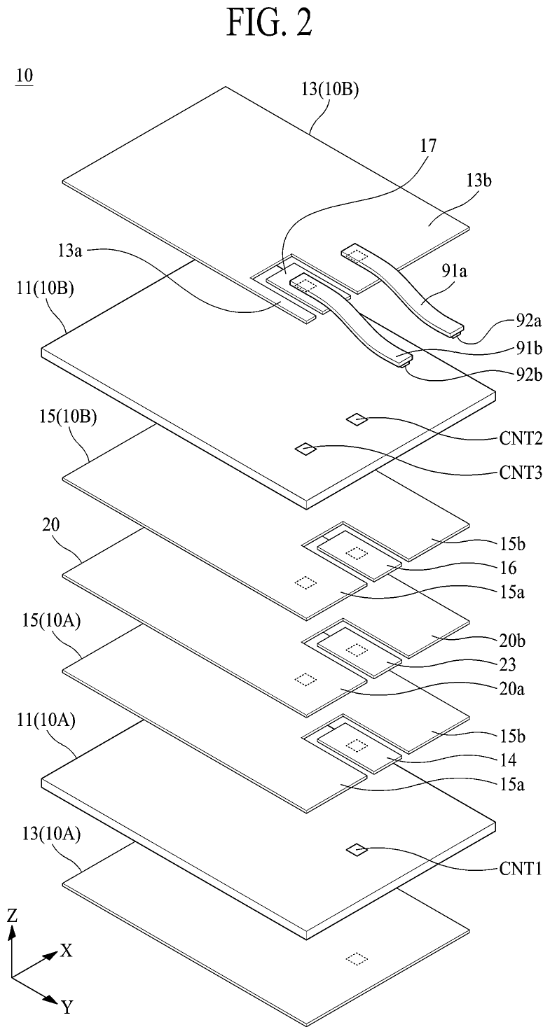

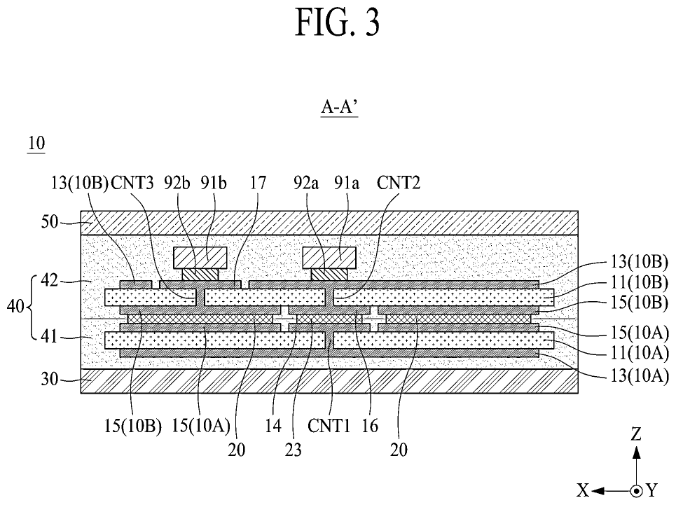

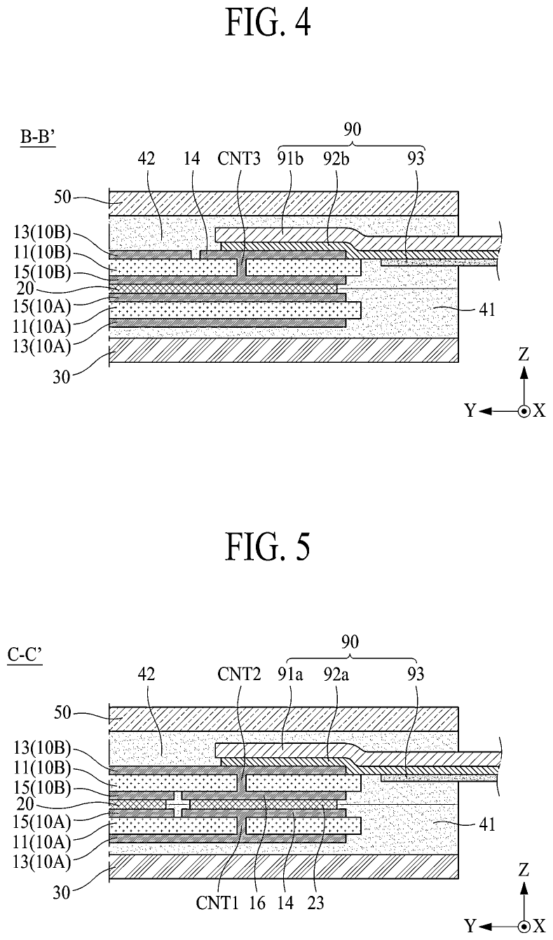

FIG. 1 illustrates a vibration apparatus according to an aspect of the present disclosure. FIG. 2 is an exploded perspective view illustrating a connection structure between a vibration generating part and a signal cable illustrated in FIG. 1 according to an aspect of the present disclosure. FIG. 3 is a cross-sectional view taken along line A-A′ illustrated in FIG. 1 according to an aspect of the present disclosure. FIG. 4 is a cross-sectional view taken along line B-B′ illustrated in FIG. 1 according to an aspect of the present disclosure. FIG. 5 is a cross-sectional view taken along line C-C′ illustrated in FIG. 1 according to an aspect of the present disclosure.

Referring to FIGS. 1 to 5, a vibration apparatus according to an aspect of the present disclosure may include a vibration generating part 10 and a connection layer 20.

The vibration generating part 10 may include a plurality of vibration parts 10A and 10B. For example, the vibration generating part 10 may include the plurality of vibration parts 10A and 10B which overlap each other or are overlaid. For example, the vibration generating part 10 may include the plurality of vibration parts 10A and 10B which are stacked or overlap each other. For example, the vibration generating part 10 may include a first vibration part 10A and a second vibration part 10B stacked on the first vibration part 10A.

According to an aspect of the present disclosure, each of the first vibration part 10A and the second vibration part 10B may include a piezoelectric material (or an electroactive material), or a piezoelectric device, which has a piezoelectric effect. For example, the piezoelectric material (or the piezoelectric device) may have a characteristic where pressure or twisting is applied to a crystal structure by an external force, a potential difference occurs due to dielectric polarization caused by a relative position change of a positive (+) ion and a negative (−) ion, and a vibration is generated by an electric field based on a voltage applied thereto.

Each of the first vibration part 10A and the second vibration part 10B may include a vibration layer 11, a first electrode layer 13, and a second electrode layer 15.

The vibration layer 11 may include a piezoelectric material (or an electroactive material) having a piezoelectric effect. The vibration layer 11 may include a ceramic-based material for implementing a relatively strong vibration, or may include piezoelectric ceramic having a perovskite-based crystalline structure.

The piezoelectric ceramic may include single crystalline ceramic having a single-crystal structure, or may include a ceramic material or polycrystalline ceramic having a poly-crystal structure. A piezoelectric material including single crystalline ceramic may include one or more of aluminum phosphate (for example, α-AlPO₄), silicon dioxide (for example, α-SiO₂), lithium niobate (LiNbO₃), terbium molydbate (Tb₂(MoO₄)₃), lithium tetraborate (Li₂B₄O₇), ZnO or a combination thereof. The piezoelectric material including single crystalline ceramic may include a lead zirconate titanate (PZT)-based material including lead (Pb), zirconium (Zr), and titanium (Ti) or may include a lead zirconate nickel niobate (PZNN)-based material including lead (Pb), zirconium (Zr), nickel (Ni), and niobium (Nb), but aspects of the present disclosure are not limited thereto. As another example, the vibration layer 11 may include at least one of CaTiO₃, BaTiO₃, and SrTiO₃ without lead (Pb), but aspects of the present disclosure are not limited thereto.

According to an aspect of the present disclosure, the vibration layer 11 of each of the first vibration part 10A and the second vibration part 10B may have a same ceramic crystalline structure, or may have different ceramic crystalline structures. For example, the vibration layer 11 of the first vibration part 10A and the vibration layer 11 of the second vibration part 10B may include single crystalline ceramic or polycrystalline ceramic. For example, one of the vibration layer 11 of the first vibration part 10A and the vibration layer 11 of the second vibration part 10B may include single crystalline ceramic, and the other may include polycrystalline ceramic.

According to an aspect of the present disclosure, in each of a first vibration part 10A and a second vibration part 10B, a vibration layer 11 may be configured (or disposed) between a first electrode layer 13 and a second electrode layer 15.

In the first vibration part 10A, the first electrode layer 13 may be disposed at a first surface (or a lower surface) of the vibration layer 11. The first electrode layer 13 may have a same size as that of the vibration layer 11 or may have a size which is less than that of the vibration layer 11, but aspects of the present disclosure are not limited thereto. For example, the first electrode layer 13 may be a single-electrode. For example, the first electrode layer 13 may include a tetragonal shape. For example, an end (or a lateral surface) of the first electrode layer 13 may be spaced apart from an end (or a lateral surface) of the vibration layer 11, and thus, an electrical connection (or short circuit) between the first electrode layer 13 and the second electrode layer 15 may be prevented. For example, the first electrode layer 13 of the first vibration part 10A may be a first electrode layer, a lower electrode layer, or a lowermost electrode layer of the vibration generating part 10, but aspects of the present disclosure are not limited thereto.

In the first vibration part 10A, the second electrode layer 15 may be disposed at a second surface (or an upper surface), which is different from or opposite to the first surface, of the vibration layer 11. The second electrode layer 15 may have a size which is less than that of the vibration layer 11, but aspects of the present disclosure are not limited thereto. For example, the second electrode layer 15 of the first vibration part 10A may be the second electrode layer of the vibration generating part 10, but aspects of the present disclosure are not limited thereto.

In an aspect of the present disclosure, in the first vibration part 10A, the second electrode layer 15 may include a plurality of protrusion portions (or a pair of protrusion portions) 15a and 15b which protrude from one end (or one side or one portion) thereof. The plurality of protrusion portions 15a and 15b may be arranged apart from each other in parallel. Accordingly, the second electrode layer 15 may not be provided in a region where the plurality of protrusion portions 15a and 15b are spaced apart from each other, and a second surface (or an upper surface) of the vibration layer 11 may be exposed.

In another aspect of the present disclosure, in the first vibration part 10A, the second electrode layer 15 may include a concave portion which is concave from a portion of one end (or one side) thereof. The concave portion may be formed to be concave in a second direction Y from a center portion of the one end (or one side) of the second electrode layer 15. For example, the concave portion may be concavely formed to have a certain length in the second direction Y from the center portion of the one end (or one side) of the second electrode layer 15. For example, the concave portion may be configured between the plurality of protrusion portions (or a pair of protrusion portions) 15a and 15b, but aspects of the present disclosure are not limited thereto. For example, the concave portion may be a portion which is formed by removing a portion of the second electrode layer 15, or may be a portion where the second electrode layer 15 is not formed. For example, the concave portion may be a patterning portion, an electrode non-formation portion, an electrode non-disposition portion, or an open portion, but aspects of the present disclosure are not limited thereto.

In the second vibration part 10B, the first electrode layer 13 may be disposed at a second surface (or an upper surface), which is different from or opposite to the first surface, of the vibration layer 11. The first electrode layer 13 may have a size which is less than that of the vibration layer 11, but aspects of the present disclosure are not limited thereto. For example, the first electrode layer 13 of the second vibration part 10B may be a third electrode layer, an upper electrode layer, or an uppermost electrode layer of the vibration generating part 10, but aspects of the present disclosure are not limited thereto.

In an aspect of the present disclosure, in the second vibration part 10B, the first electrode layer 13 may include a plurality of protrusion portions (or a pair of protrusion portions) 13a and 13b which protrude (or extend) from one end (or one side or one portion) of the first electrode layer 13. The plurality of protrusion portions 13a and 13b may be arranged apart from each other in parallel. Accordingly, the first electrode layer 13 may not be provided in a region where the plurality of protrusion portions 13a and 13b are spaced apart from each other, and the second surface (or the upper surface) of the vibration layer 11 may be exposed.

In another aspect of the present disclosure, in the second vibration part 10B, the first electrode layer 13 may include a concave portion which is concave from a portion of the one end (or one side) thereof. The concave portion may be formed to be concave in the second direction Y from a center portion of the one end (or one side or one portion) of the first electrode layer 13. For example, the concave portion may be concavely formed to have a certain (or pre-defined) length in the second direction Y from the center portion of the one end (or one side or one portion) of the first electrode layer 13. For example, the concave portion may be configured between the plurality of protrusion portions (or a pair of protrusion portions) 13a and 13b, but aspects of the present disclosure are not limited thereto. For example, the concave portion may be a portion which is formed by removing a portion of the first electrode layer 13, or may be a portion where the first electrode layer 13 is not formed. For example, the concave portion may be a patterning portion, an electrode non-formation portion, an electrode non-disposition portion, or an open portion, but aspects of the present disclosure are not limited thereto.

In the second vibration part 10B, the second electrode layer 15 may be disposed at the first surface (or the lower surface), which is different from or opposite to the second surface, of the vibration layer 11. The second electrode layer 15 may have a size which is less than that of the vibration layer 11, but aspects of the present disclosure are not limited thereto. For example, the second electrode layer 15 of the second vibration part 10B may be a fourth electrode layer of the vibration generating part 10, but aspects of the present disclosure are not limited thereto.

In an aspect of the present disclosure, in the second vibration part 10B, the second electrode layer 15 may include a plurality of protrusion portions (or a pair of protrusion portions) 15a and 15b which protrude (or extend) from one end (or one side or one portion) thereof. The plurality of protrusion portions 15a and 15b may be arranged to be spaced apart from each other in parallel. Accordingly, the second electrode layer 15 may not be provided in a region where the plurality of protrusion portions 15a and 15b are spaced apart from each other, and the first surface (or the lower surface) of the vibration layer 11 may be exposed.

In another aspect of the present disclosure, in the second vibration part 10B, the second electrode layer 15 may include a concave portion which is concave from a portion of the one end (or one side) thereof. The concave portion may be formed to be concave in the second direction Y from the center portion of the one end (or one side) of the second electrode layer 15. For example, the concave portion may be concavely formed to have a certain length in the second direction Y from the center portion of the one end (or one side or one portion) of the second electrode layer 15. For example, the concave portion may be configured between the plurality of protrusion portions (or a pair of protrusion portions) 15a and 15b, but aspects of the present disclosure are not limited thereto. For example, the concave portion may be a portion which is formed by removing a portion of the second electrode layer 15, or may be a portion where the second electrode layer 15 is not formed. For example, the concave portion may be a patterning portion, an electrode non-formation portion, an electrode non-disposition portion, or an open portion, but aspects of the present disclosure are not limited thereto.

According to an aspect of the present disclosure, the second electrode layer 15 of the second vibration part 10B and the first electrode layer 13 of the second vibration part 10B may have different shapes. For example, the plurality of protrusion portions 15a and 15b configured in the second electrode layer 15 of the second vibration part 10B and the plurality of protrusion portions 13a and 13b configured in the first electrode layer 13 of the second vibration part 10B may have a non-overlap region which does not overlap each other. For example, the concave portion configured in the second electrode layer 15 of the second vibration part 10B may not overlap the concave portion configured in the first electrode layer 13 of the second vibration part 10B. For example, the concave portion configured in the second electrode layer 15 of the second vibration part 10B and the concave portion configured in the first electrode layer 13 of the second vibration part 10B may be configured not to face each other, but aspects of the present disclosure are not limited thereto.

According to an aspect of the present disclosure, the plurality of protrusion portions 15a and 15b configured in the second electrode layer 15 of the first vibration part 10A and the plurality of protrusion portions 13a and 13b configured in the first electrode layer 13 of the second vibration part 10B may overlap each other. For example, the concave portion configured in the second electrode layer 15 of the first vibration part 10A may overlap the concave portion configured in the second electrode layer 15 of the second vibration part 10B. For example, the second electrode layer 15 of the first vibration part 10A and the second electrode layer 15 of the second vibration part 10B may be disposed to be adjacent to each other. According to an aspect of the present disclosure, because the second electrode layer 15 of the first vibration part 10A and the second electrode layer 15 of the second vibration part 10B are disposed to be adjacent to each other, a polarization direction (or a poling direction) formed in the vibration layer 11 of the first vibration part 10A and a polarization direction (or a poling direction) formed in the vibration layer 11 of the second vibration part 10B may be different directions or opposite directions. For example, a polarization direction (or a poling direction) formed in each of the vibration layer 11 of the first vibration part 10A and the vibration layer 11 of the second vibration part 10B may be a direction from the first electrode layer 13 to the second electrode layer 15.

According to an aspect of the present disclosure, the first electrode layer 13 of the second vibration part 10B and the second electrode layer 15 of the first vibration part 10A may have different shapes. For example, the plurality of protrusion portions 13a and 13b configured in the first electrode layer 13 of the second vibration part 10B and the plurality of protrusion portions 15a and 15b configured in the second electrode layer 15 of the first vibration part 10A may have a non-overlap region which does not overlap each other. For example, the concave portion configured in the first electrode layer 13 of the second vibration part 10B may not overlap the concave portion configured in the second electrode layer 15 of the first vibration part 10A. For example, the concave portion configured in the first electrode layer 13 of the second vibration part 10B and the concave portion configured in the second electrode layer 15 of the first vibration part 10A may be configured not to face each other, but aspects of the present disclosure are not limited thereto.

In a stack structure of the first and second vibration parts 10A and 10B, to prevent electrical short circuit between electrode layers vertically adjacent to each other, each of the first electrode layer 13 and the second electrode layer 15 may be formed at the other portion, except an edge portion of the vibration layer 11. For example, a distance between a lateral surface of each of the first electrode layer 13 and the second electrode layer 15, and a lateral surface of the vibration layer 11 may be at least 0.5 mm or more, but aspects of the present disclosure are not limited thereto. For example, the distance between the lateral surface of each of the first electrode layer 13 and the second electrode layer 15, and the lateral surface of the vibration layer 11 may be at least 1 mm or more, but aspects of the present disclosure are not limited thereto.

According to an aspect of the present disclosure, one or more of the first electrode layer 13 and the second electrode layer 15 may include material fired at a high temperature (for example, 650° C. or lower). For example, one or more of the first electrode layer 13 and the second electrode layer 15 may include a transparent conductive material, a semitransparent conductive material, or an opaque conductive material, but aspects of the present disclosure are not limited thereto. For example, the transparent or semitransparent conductive material may include one or more of indium tin oxide (ITO) or indium zinc oxide (IZO), but aspects of the present disclosure are not limited thereto. The opaque conductive material may include one or more of glass frit including gold (Au), silver (Ag), platinum (Pt), palladium (Pd), molybdenum (Mo), magnesium (Mg), carbon, or silver (Ag), or an alloy thereof, but aspects of the present disclosure are not limited thereto. For example, carbon may be a carbon material including carbon black, ketjen black, carbon nanotube, and graphite, but aspects of the present disclosure are not limited thereto. According to an aspect of the present disclosure, each of the first electrode layer 13 and the second electrode layer 15 may include silver (Ag) having a low resistivity, to enhance an electrical characteristic and/or a vibration characteristic of the vibration layer 11.

In the first electrode layer 13 and the second electrode layer 15 including glass frit including silver (Ag), a content of glass frit may be about 1 wt % or more to about 12 wt % or less, but aspects of the present disclosure are not limited thereto. The glass frit may include a material based on PbO or Bi₂O₃, but aspects of the present disclosure are not limited thereto. For example, the glass frit may include one material of oxides of bismuth (Bi), zinc (Zn), aluminum (Al), boron (B), and silicone (Si). In this regard, the glass frit may include, for example, an oxide of bismuth (Bi), an oxide of zinc (Zn), an oxide of aluminum (Al), an oxide of boron (B), and/or an oxide of silicone (Si). However, aspects of the present disclosure are not limited to foregoing.

The vibration generating part 10 or the first vibration part 10A according to an aspect of the present disclosure may further include a first auxiliary electrode layer 14.

In the first vibration part 10A, the first auxiliary electrode layer 14 may be configured (or formed) on the vibration layer 11 to be electrically disconnected from the second electrode layer 15. The first auxiliary electrode layer 14 may be configured (or formed) on a second surface of the vibration layer 11 to be electrically disconnected from the second electrode layer 15. For example, the first auxiliary electrode layer 14 may be configured (or formed) on the vibration layer 11 between the plurality of protrusion portions 15a and 15b in the second electrode layer 15.

In the first vibration part 10A, the first auxiliary electrode layer 14 may be electrically connected to the first electrode layer 13 through the vibration layer 11. For example, the first auxiliary electrode layer 14 may be electrically connected to the first electrode layer 13 through a first contact hole CNT1 which is configured (or formed) in the vibration layer 11. For example, in the first vibration part 10A, the first contact hole CNT1 overlapping the first auxiliary electrode layer 14 may be configured in one end (or one side) of the vibration layer 11. The first contact hole CNT1 may overlap the first electrode layer 13 and the first auxiliary electrode layer 14. The first auxiliary electrode layer 14 may electrically contact the first electrode layer 13 through the first contact hole CNT1. The first auxiliary electrode layer 14 may be connected to the first electrode layer 13 through the first contact hole CNT1 configured in the one side of the vibration layer 11.

According to an aspect of the present disclosure, the vibration generating part 10 or the second vibration part 10B according to an aspect of the present disclosure may further include a second auxiliary electrode layer 16 and a third auxiliary electrode layer 17.

In the second vibration part 10B, the second auxiliary electrode layer 16 may be configured (or formed) on the vibration layer 11 to be electrically disconnected from the second electrode layer 15. The second auxiliary electrode layer 16 may be configured (or formed) on a first surface of the vibration layer 11 to be electrically disconnected from the second electrode layer 15. For example, the second auxiliary electrode layer 16 may be configured (or formed) on the vibration layer 11 between the plurality of protrusion portions 15a and 15b in the second electrode layer 15. The second auxiliary electrode layer 16 may overlap the first auxiliary electrode layer 14 of the first vibration part 10A.

In the second vibration part 10B, the second auxiliary electrode layer 16 may be electrically connected to the first electrode layer 13 through the vibration layer 11. For example, the second auxiliary electrode layer 15 may be electrically connected to the first electrode layer 13 through a second contact hole CNT2 which is configured (or formed) in the vibration layer 11. For example, in the second vibration part 10B, the second contact hole CNT2 overlapping the second auxiliary electrode layer 16 may be configured in one end (or one side or one portion) of the vibration layer 11. The second contact hole CNT2 may overlap the first electrode layer 13 and the second auxiliary electrode layer 16. The second auxiliary electrode layer 16 may electrically contact the first electrode layer 13 through the second contact hole CNT2. The second auxiliary electrode layer 16 may be connected to the first electrode layer 13 through the second contact hole CNT2 configured in the one side of the vibration layer 11.

In the second vibration part 10B, the third auxiliary electrode layer 17 may be configured (or formed) on the vibration layer 11 to be electrically disconnected from the first electrode layer 13. The third auxiliary electrode layer 17 may be configured (or formed) on a second surface of the vibration layer 11 to be electrically disconnected from the first electrode layer 13. For example, the third auxiliary electrode layer 17 may be configured (or formed) on the vibration layer 11 between the plurality of protrusion portions 13a and 13b in the first electrode layer 13.

In the second vibration part 10B, the third auxiliary electrode layer 17 may be electrically connected to the second electrode layer 15 through the vibration layer 11. For example, the third auxiliary electrode layer 17 may be electrically connected to the first electrode layer 13 through the second contact hole CNT2 which is configured (or formed) in the vibration layer 11. For example, in the second vibration part 10B, the third contact hole CNT3 overlapping the third auxiliary electrode layer 17 may be configured in one end (or one side) of the vibration layer 11. The third contact hole CNT3 may overlap the second electrode layer 15 and the third auxiliary electrode layer 17. The third auxiliary electrode layer 17 may electrically contact the second electrode layer 15 through the third contact hole CNT3. The third auxiliary electrode layer 17 may be connected to the second electrode layer 15 through the third contact hole CNT3 configured in the one side of the vibration layer 11.

According to an aspect of the present disclosure, the plurality of vibration parts 10A and 10B or the first and second vibration parts 10A and 10B may be connected to or contact each other. The plurality of vibration parts 10A and 10B may be connected to each other through the connection layer 20 configured between the plurality of vibration parts 10A and 10B. For example, the plurality of vibration parts 10A and 10B or the first and second vibration parts 10A and 10B may contact each other through the connection layer 20.

The second electrode layer 15 of the first vibration part 10A may contact or be electrically connected to the second electrode layer 15 of the second vibration part 10B. For example, the second electrode layer 15 of the first vibration part 10A may contact or be electrically connected to the second electrode layer 15 of the second vibration part 10B by the connection layer 20.

According to an aspect of the present disclosure, the connection layer 20 may include a conductive material. For example, the conductive material may include copper (Cu) or silver (Ag), but aspects of the present disclosure are not limited thereto. According to an aspect of the present disclosure, the connection layer 20 may include a glass frit including Ag. For example, in the connection layer 20, a content of the glass frit may be 50 wt % to 70 wt %. For example, when a content of the glass frit is less than 50 wt %, the uniformity of surface coating of the connection layer 20 and an interface adhesive force between the connection layer 20 and the second electrode layer 15 may be reduced. For example, when a content of the glass frit is 70 wt % or more, an electrical connection between the connection layer 20 and each of the second electrode layer 15 of the first vibration part 10A and the second electrode layer 15 of the second vibration part 10B may be unstable. For example, in the connection layer 20, a content of Ag may be 20 wt % or less. For example, the glass frit may include a PbO or Bi₂O₃-based material, but aspects of the present disclosure are not limited thereto. For example, the glass frit may include one material of oxides of bismuth (Bi), zinc (Zn), aluminum (Al), boron (B), and silicone (Si), but aspects of the present disclosure are not limited thereto. For example, in the connection layer 20, a particle size of the glass frit may be 5 μm or less. For example, when a particle size of the glass frit is more than 5 μm, the glass frit may not be smoothly melted in a firing process, and thus, the surface uniformity of the connection layer 20 may be reduced. For example, the glass frit may be a material of a flake type where a surface area is wide. Accordingly, manufacturing may be easy, a thin film of a uniform glass frit may be configured, and thus, the connection layer 20 where a surface is uniform may be configured. According to an aspect of the present disclosure, the connection layer 20 may be an internal connection layer or an electrode connection layer, but aspects of the present disclosure are not limited thereto.

According to an aspect of the present disclosure, the connection layer 20 may include a plurality of protrusion portions (or a pair of protrusion portions) 20a and 20b which protrude (or extend) from one end (or one side) thereof. The plurality of protrusion portions 20a and 20b may be arranged apart from each other in parallel. Accordingly, the connection layer 20 may not be provided in a region where the plurality of protrusion portions 20a and 20b are spaced apart from each other. In another aspect of the present disclosure, the connection layer 20 may include a concave portion which is concave from a portion of the one end (or one side) of the connection layer 20. The concave portion may be formed to be concave in the second direction Y from a center portion of the one end (or one side or one portion) of the connection layer 20. For example, the concave portion may be concavely formed to have a certain length in the second direction Y from the center portion of the one end (or one side or one portion) of the connection layer 20. For example, the concave portion may be configured between the plurality of protrusion portions (or a pair of protrusion portions) 20a and 20b, but aspects of the present disclosure are not limited thereto. For example, the concave portion may be a portion where the connection layer 20 is not formed and may thus be a patterning portion or an open portion, but aspects of the present disclosure are not limited thereto.

According to an aspect of the present disclosure, an auxiliary connection layer 23 may be configured between the plurality of protrusion portions (or a pair of protrusion portions) 20a and 20b which protrude (or extend) from the one end (or one side or one portion) of the connection layer 20. For example, the auxiliary connection layer 23 may be spaced apart from the connection layer 20, in the same layer as the connection layer 20. For example, the auxiliary connection layer 23 may be disposed at the concave portion configured between the plurality of protrusion portions (or a pair of protrusion portions) 20a and 20b.

According to an aspect of the present disclosure, the auxiliary connection layer 23 may be configured between the first auxiliary electrode layer 14 and the second auxiliary electrode layer 16 to connect the first auxiliary electrode layer 14 to the second auxiliary electrode layer 16. The auxiliary connection layer 23 may overlap the first auxiliary electrode layer 14 and the second auxiliary electrode layer 16. For example, the auxiliary connection layer 23 may include the same material as that of the connection layer 20 and may be formed by using the same process, but embodiments of the present disclosure are not limited thereto. For example, the auxiliary connection layer 23 may include a glass frit and silver (Ag) having the same contents as the connection layer 20. Accordingly, the auxiliary connection layer 23 may be the same as the description of the connection layer 20, and thus, repeated descriptions thereof may be omitted.

According to an aspect of the present disclosure, the first vibration part 10A may include the first auxiliary electrode layer 14. The first auxiliary electrode layer 14 may be disposed at the second surface (or an upper surface), which is different from or opposite to the first surface, of the vibration layer 11 configured in the first vibration part 10A.

In the first vibration part 10A, the first auxiliary electrode layer 14 may be configured at an area of the upper surface of the vibration layer 11 where the second electrode layer 15 is not provided. For example, the first auxiliary electrode layer 14 may be configured between the plurality of protrusion portions (or a pair of protrusion portions) 15a and 15b which protrude (or extend) from the one end (or one side or one portion) of the connection layer 20. For example, the first auxiliary electrode layer 14 may be space apart from the second electrode layer 15, in the same layer as the second electrode layer 15. For example, the first auxiliary electrode layer 14 may be disposed at the concave portion configured between the plurality of protrusion portions (or a pair of protrusion portions) 15a and 15b.

In the first vibration part 10A, the first auxiliary electrode layer 14 may be connected to the first electrode layer 13 of the first vibration part 10A through the first contact hole CNT1 configured in the vibration layer 11 of the first vibration part 10A. The first auxiliary electrode layer 14 may be connected to the second auxiliary electrode layer 16 through the auxiliary connection layer 23. The first electrode layer 13 of the first vibration part 10A may be connected to the first electrode layer 13 of the second vibration part 10B through the first auxiliary electrode layer 14, the auxiliary connection layer 23, and the second auxiliary electrode layer 16. For example, the first auxiliary electrode layer 14 may be at the second surface of the vibration layer 11 of the first vibration part 10A to be electrically disconnected from the connection layer 20 and the second electrode layer 15 of the first vibration part 10A and may be electrically connected to the first electrode layer 13 of the first vibration part 10A. For example, the first electrode layer 13, the first auxiliary electrode layer 14, and the auxiliary connection layer 23 of the first vibration part 10B and the first electrode layer 13 of the second vibration part 10B may be sequentially connected to one another. For example, the first auxiliary electrode layer 14 may include the same material as that of the second electrode layer 15 of the first vibration part 10A and may be formed by the same process, but aspects of the present disclosure are not limited thereto.

The second vibration part 10B may include the second auxiliary electrode layer 16 and the third auxiliary electrode layer 17. The second auxiliary electrode layer 16 and the third auxiliary electrode layer 17 may not overlap each other, but aspects of the present disclosure are not limited thereto.

In the second vibration part 10B, the second auxiliary electrode layer 16 may be disposed at the first surface (or the lower surface), which is different from or opposite to the second surface (or the upper surface), of the vibration layer 11. The second auxiliary electrode layer 16 may be configured at the lower surface of the vibration layer 11 where the second electrode layer 15 is not provided. For example, the second auxiliary electrode layer 16 may be configured between the plurality of protrusion portions (or a pair of protrusion portions) 15a and 15b protruding (or extending) from the one end (or one side or one portion) of the second electrode layer 15. For example, the second auxiliary electrode layer 16 may be spaced apart from the second electrode layer 15, in a same layer as the second electrode layer 15. For example, the second auxiliary electrode layer 16 may be disposed at the concave portion configured between the plurality of protrusion portions (or a pair of protrusion portions) 15a and 15b.

In the second vibration part 10B, the second auxiliary electrode layer 16 may be connected to the first electrode layer 13 of the second vibration part 10B through the second contact hole CNT2 configured in the vibration layer 11. For example, the second auxiliary electrode layer 16 may be electrically disconnected from the connection layer 20 and the second electrode layer 15 of the second vibration part 10B. For example, the second auxiliary electrode layer 16 may be electrically connected to the first auxiliary electrode layer 14 and may be electrically connected to the first electrode layer 13 of the second vibration part 10B. For example, the first electrode layer 13 of the second vibration part 10B may be connected to the first electrode layer 13 of the first vibration part 10A through the second auxiliary electrode layer 16, the auxiliary connection layer 23, and the first auxiliary electrode layer 14. For example, the second auxiliary electrode layer 16 may include the same material as that of the second electrode layer 15 of the second vibration part 10B and may be formed by using the same process, but aspects of the present disclosure are not limited thereto.

According to an aspect of the present disclosure, each of the first electrode layer 13, the second electrode layer 15, and the first to third auxiliary electrode layers 14, 16, and 17 may include Ag. According to an aspect of the present disclosure, each of the first electrode layer 13, the second electrode layer 15, and the first to third auxiliary electrode layers 14, 16, and 17 may include a glass frit. However, aspects of the present disclosure are not limited thereto.

According to an aspect of the present disclosure, the second auxiliary electrode layer 16, the auxiliary connection layer 23, and the first auxiliary electrode layer 14 may be sequentially configured and may be electrically connected to one another, and thus, the first electrode layer 13 of the second vibration part 10B connected to the second auxiliary electrode layer 16 through the second contact hole CNT2, and the first electrode layer 13 of the first vibration part 10A connected to the first auxiliary electrode layer 14 through the first contact hole CNT1 may be electrically connected.

According to an aspect of the present disclosure, the first electrode layer 13 of the second vibration part 10B may contact a first signal line 92a. Therefore, the first electrode layer 13, and the second auxiliary electrode layer 16 of the second vibration part 10B, the auxiliary connection layer 23, the first auxiliary electrode layer 14, and the first electrode layer 13 of the first vibration part 10A may be electrically connected to the first signal line 92a. Therefore, the first electrode layer 13 of the first vibration part 10A and the first electrode layer 13 of the second vibration part 10B may be electrically connected to the first signal line 92a.

Therefore, in an aspect of the present disclosure, a separate signal line may not be configured at the lower surface (or a lower side or a lower portion) of the first electrode layer 13 of the first vibration part 10A, and the same signal may be applied to the first electrode layer 13 of the first vibration part 10A and the first electrode layer 13 of the second vibration part 10B by one signal line (for example, a first signal line).

In the second vibration part 10B, the third auxiliary electrode layer 17 may be disposed at the second surface (or the upper surface), which is different from or opposite to the first surface (or the lower surface or the lower portion), of the vibration layer 11. For example, the third auxiliary electrode layer 17 may be configured at an area of the upper surface of the vibration layer 11 on which the first electrode layer 13 is not provided. For example, the third auxiliary electrode layer 17 may be configured between the plurality of protrusion portions (or a pair of protrusion portions) 13a and 13b which protrude (or extend) from the one end (or one side or one portion) of the first electrode layer 13. For example, the third auxiliary electrode layer 17 may be spaced apart from the first electrode layer 13, in the same layer as the first electrode layer 13. For example, the third auxiliary electrode layer 17 may be disposed at the concave portion configured between the plurality of protrusion portions (or a pair of protrusion portions) 13a and 13b.

In the second vibration part 10B, the third auxiliary electrode layer 17 may be connected to the second electrode layer 15 of the second vibration part 10B through the third contact hole CNT3 configured in the vibration layer 11. For example, the connection layer 20 may be configured between the second electrode layer 15 of the second vibration part 10B and the second electrode layer 15 of the first vibration part 10A. For example, the second electrode layer 15 of the second vibration part 10B and the second electrode layer 15 of the first vibration part 10A may be connected to each other through the connection layer 20. For example, the third auxiliary electrode layer 17 may be at the second surface (or the upper surface) of the vibration layer 11 to be electrically disconnected from the first electrode layer 13 of the second vibration part 10B and may be electrically connected to the second electrode layer 15 of the second vibration part 10B through the third contact hole CNT3 configured in the vibration layer 11.

According to an aspect of the present disclosure, the third auxiliary electrode layer 17, the second electrode layer 15 of the second vibration part 10B, the connection layer 20, and the second electrode layer 15 of the first vibration part 10A may be sequentially configured. For example, the third auxiliary electrode layer 17, the second electrode layer 15 of the second vibration part 10B, the connection layer 20, and the second electrode layer 15 of the first vibration part 10A may be electrically connected to one another. For example, the third auxiliary electrode layer 17 and the second electrode layer 15 of the second vibration part 10B may be electrically connected to each other through the third contact hole CNT3, and the second electrode layer 15 of the second vibration part 10B and the second electrode layer 15 of the first vibration part 10A may be electrically connected to each other through the connection layer 20. For example, the third auxiliary electrode layer 17 may include a same material as that of the first electrode layer 13 of the second vibration part 10B and may be formed by using the same process, but aspects of the present disclosure are not limited thereto.

According to an aspect of the present disclosure, the third auxiliary electrode layer 17 may not overlap the first auxiliary electrode layer 14 and the second auxiliary electrode layer 16, but aspects of the present disclosure are not limited thereto. For example, the third contact hole CNT3 connecting the third auxiliary electrode layer 17 to the second electrode layer 15 of the second vibration part 10B may not overlap the first contact hole CNT1 and the second contact hole CNT2. Accordingly, short circuit between the third auxiliary electrode layer 17, the second electrode layer 15 of the second vibration part 10B, and the second electrode layer 15 of the first vibration part 10A may be prevented, and the third auxiliary electrode layer 17, the second electrode layer 15 of the second vibration part 10B, and the second electrode layer 15 of the first vibration part 10A may be easily connected to one another.

According to an aspect of the present disclosure, the third auxiliary electrode layer 17 may contact a second signal line 92b. Therefore, the second electrode layer 15 of the second vibration part 10B, the connection layer 20, and the second electrode layer 15 of the first vibration part 10A may be electrically connected to the second signal line 92b through the third auxiliary electrode layer 17. For example, the second electrode layer 15 of the second vibration part 10B and the second electrode layer 15 of the first vibration part 10A may each be a middle electrode layer, an internal electrode layer, and a common electrode layer of the vibration generating part 10, but aspects of the present disclosure are not limited thereto.

The vibration layer 11 of the first vibration part 10A and the vibration layer 11 of the second vibration part 10B may be polarized (or poling) in the same direction, or may be polarized (or poling) in opposite (or different) directions. For example, a polarization direction (or a poling direction) formed in the vibration layer 11 of the first vibration part 10A may be a direction which is different from or opposite to a polarization direction (or a poling direction) formed in the vibration layer 11 of the second vibration part 10B.

According to an aspect of the present disclosure, the second electrode layer 15 of the first vibration part 10A and the second electrode layer 15 of the second vibration part 10B may be connected to each other, and thus, when a polarization direction (or a poling direction) formed in the vibration layer 11 of the first vibration part 10A is a direction which is different from or opposite to a polarization direction (or a poling direction) formed in the vibration layer 11 of the second vibration part 10B, the first vibration part 10A and the second vibration part 10B may be displaced (or vibrated or driven) in the same direction, and thus, a vibration width (or displacement width or driving width) of the vibration generating part 10 may be maximized, thereby enhancing a sound pressure level characteristic of the vibration generating part 10.

The vibration generating part 10 according to an aspect of the present disclosure may further include a first cover member 30.

The first cover member 30 may be configured to protect a first surface of the vibration generating part 10. For example, the first surface of the vibration generating part 10 may be a lower surface, a rear surface, a rearmost surface, a backside surface, or a backside portion.

The first cover member 30 may be configured to cover the first vibration part 10A of the vibration generating part 10. For example, the first cover member 30 may be configured to cover the first electrode layer 13 of the first vibration part 10A. Accordingly, the first cover member 30 may protect the first surface of the vibration generating part 10 and the first electrode layer 13 of the first vibration part 10A.

The first cover member 30 according to an aspect of the present disclosure may include an adhesive member. For example, the first cover member 30 may include a base cover member and an adhesive member which is in the base cover member and is connected or coupled to the first surface of the vibration generating part 10 and the first electrode layer 13 of the first vibration part 10A. For example, the adhesive member may include an electrical insulating material which has adhesive properties and is capable of compression and decompression.

According to another aspect of the present disclosure, the first cover member 30 may be connected or coupled to the first surface of the vibration generating part 10 by an adhesive layer 40. For example, the first cover member 30 may be connected or coupled to at least a portion of the first electrode layer 13 of the first vibration part 10A or the first surface of the vibration generating part 10 by using a first adhesive layer 41. For example, the first cover member 30 may be connected or coupled to at least a portion of the first electrode layer 13 of the first vibration part 10A or the first surface of the vibration generating part 10 by a film laminating process by using the first adhesive layer 41.

The vibration generating part 10 according to an aspect of the present disclosure may further include a second cover member 50.

The second cover member 50 may be configured to cover a second surface of the vibration generating part 10. For example, the second surface of the vibration generating part 10 may be an upper surface, an uppermost surface, a front surface, or a front portion. The second cover member 50 may be configured to cover the second vibration part 10B of the vibration generating part 10. For example, the second cover member 50 may be configured to cover the first electrode layer 13 and the third auxiliary electrode layer 17 of the second vibration part 10B. Accordingly, the second cover member 50 may protect the second surface of the vibration generating part 10 and the first electrode layer 13 and the third auxiliary electrode layer 17 of the second vibration part 10B.

The second cover member 50 according to an aspect of the present disclosure may include an adhesive member. For example, the second cover member 50 may include a base cover member and an adhesive member which is in the base cover member and is connected or coupled to the second surface of the vibration generating part 10 and the first electrode layer 13 of the first vibration part 10A. For example, the adhesive member may include an electrical insulating material which has adhesive properties and is capable of compression and decompression.

According to another aspect of the present disclosure, the second cover member 50 may be connected or coupled to the second surface of the vibration generating part 10 by using the adhesive layer 40. For example, the second cover member 50 may be connected or coupled to at least a portion of the first electrode layer 13 of the second vibration part 10B or the second surface of the vibration generating part 10 by using a second adhesive layer 42. For example, the second cover member 50 may be connected or coupled to at least a portion of the first electrode layer 13 of the second vibration part 10B or the second surface of the vibration generating part 10 by a film laminating process by using the second adhesive layer 42.

Each of the first cover member 30 and the second cover member 50 according to an example aspect of the present disclosure may include one or more materials of plastic, fiber, cloth, paper, leather, rubber, and wood, but aspects of the present disclosure are not limited thereto. For example, the first cover member 30 and the second cover member 50 may include the same material or different materials. For example, each of the first cover member 30 and the second cover member 50 may be a polyimide film or a polyethylene terephthalate film, but aspects of the present disclosure are not limited thereto.

The first adhesive layer 41 and the second adhesive layer 42 (or the adhesive layer 40) according to an aspect of the present disclosure may include an electrical insulating material which has adhesive properties and is capable of compression and decompression. For example, the first adhesive layer 41 and the second adhesive layer 42 (or the adhesive layer 40) may include epoxy resin, acrylic resin, silicone resin, urethane resin, pressure sensitive adhesive (PSA), optically cleared adhesive (OCA), or optically cleared resin (OCR), but aspects of the present disclosure are not limited thereto. For example, the first adhesive layer 41 and the second adhesive layer 42 (or the adhesive layer 40) may be configured to surround or fully surround the vibration generating part 10. The first adhesive layer 41 and the second adhesive layer 42 (or the adhesive layer 40) may be configured to cover or surround all surfaces of the vibration generating part 10. For example, the vibration generating part 10 may be inserted (or accommodated) into the adhesive layer 40, or may be buried in the adhesive layer 40.

According to an aspect of the present disclosure, one of the first cover member 30 and the second cover member 50 may be omitted. For example, the first cover member 30 of the first cover member 30 and the second cover member 50 may be omitted. When the first cover member 30 is omitted, the first surface of the vibration generating part 10 may be covered or surrounded by the adhesive layer 40 or the first adhesive layer 41, and thus, the first surface of the vibration generating part 10 may be covered or protected by the adhesive layer 40 or the first adhesive layer 41. When the first cover member 30 is omitted, the second cover member 50 may be a cover member, a cover film, a protection member, or a protection film.

The vibration apparatus according to an aspect of the present disclosure may further include a signal cable 90.

The signal cable 90 may be implemented to be connected to each of the first and second vibration parts 10A and 10B of the vibration generating part 10 at one side of the vibration generating part 10. The signal cable 90 may be connected to each of the first and second vibration parts 10A and 10B, between the first cover member 30 and the second cover member 50.

An end portion (or a distal end portion) of the signal cable 90 may be disposed at or inserted (or accommodated) into a portion between one periphery portion of the first cover member 30 and one periphery portion of the second cover member 50. The one periphery portion of the first cover member 30 and the one periphery portion of the second cover member 50 may accommodate or vertically cover a portion of the signal cable 90. Accordingly, the signal cable 90 may be provided as one body with the vibration generating part 10. For example, the vibration apparatus according to an example aspect of the present disclosure may be a vibration apparatus which is provided as one body with the signal cable 90. For example, the signal cable 90 may be configured as a flexible cable, a flexible printed circuit cable, a flexible flat cable, a single-sided flexible printed circuit, a single-sided flexible printed circuit board (PCB), a flexible multilayer printed circuit, or a flexible multilayer PCB, but aspects of the present disclosure are not limited thereto.

The signal cable 90 according to another aspect of the present disclosure may include a base member 91 and a plurality of signal lines 92a and 92b. For example, the signal cable 90 may include the base member 91, a first signal line 92a, and a second signal line 92b.

The base member 91 may include a transparent or an opaque plastic material. For example, the base member 91 may include one or more of synthetic resins such as fluorine resin, polyimide-based resin, polyurethane-based resin, polyester-based resin, polyethylene-based resin, and polypropylene-based resin, but aspects of the present disclosure are not limited thereto. The base member 91 may be a base film or a base insulation film, but aspects of the present disclosure are not limited thereto.

The base member 91 may have a certain width in a first direction X and may extend lengthwise along the second direction Y intersecting with the first direction X.

The first and second signal lines 92a and 92b may be disposed at a first surface of the base member 91 in parallel with the second direction Y and may be spaced apart or separated from each other in a first direction X. The first and second signal lines 92a and 92b may be disposed in parallel with the first surface of the base member 91. For example, each of the first and second signal lines 92a and 92b may be implemented in a line shape by patterning of a metal layer (or a conductive layer) formed or deposited on the first surface of the base member 91.

End portions (or distal end portions) of the first and second signal lines 92a and 92b may be separated from each other, and thus, may be individually curved or bent.

According to an aspect of the present disclosure, the end portion of the first signal line 92a may be disposed between the second cover member 50 and the second surface of the vibration generating part 10. For example, the end portion of the first signal line 92a may be configured to be electrically connected to an uppermost electrode layer (or a first electrode layer) 13 of the vibration generating part 10. For example, an end portion of the first signal line 92a electrically connected to an uppermost electrode layer (or a first electrode layer) 13 of the vibration generating part 10 may be covered by the adhesive layer 40 or the second adhesive layer 42, but aspects of the present disclosure are not limited thereto. For example, the end portion of the first signal line 92a electrically connected to the uppermost electrode layer (or the first electrode layer) 13 of the vibration generating part 10 may not be covered by the adhesive layer 40 or the second adhesive layer 42 and may contact or directly contact the second cover member 50.

The end portion of the first signal line 92a may be electrically connected to at least a portion of the first electrode layer 13 of the second vibration part 10B which is the uppermost electrode layer 13 of the vibration generating part 10.

For example, the first signal line 92a may be electrically connected to the first electrode layer 13 of the first vibration part 10A through the first electrode layer 13 of the second vibration part 10B, the second contact hole CNT2, the second auxiliary electrode layer 16, the auxiliary connection layer 23, the first auxiliary electrode layer 14, and the first contact hole CNT1. Therefore, the first signal line 92a may be electrically connected to the first electrode layer 13 of the second vibration part 10B and the first electrode layer 13 of the first vibration part 10A. A signal applied to the first signal line 92a may be supplied to the first electrode layer 13 of the first vibration part 10A through the first electrode layer 13 of the second vibration part 10B, the second contact hole CNT2, the second auxiliary electrode layer 16, the auxiliary connection layer 23, the first auxiliary electrode layer 14, and the first contact hole CNT1. Therefore, the first signal line 92a may transfer a driving signal, supplied from a vibration driving circuit, to the first electrode layer 13 of the second vibration part 10B and the first electrode layer 13 of the first vibration part 10A in common. Accordingly, in an aspect of the present disclosure, two separate signal lines respectively connected to the first electrode layer 13 of the first vibration part 10A and the first electrode layer 13 of the second vibration part 10B may not be provided, and the same signal may be applied to the first electrode layer 13 of the first vibration part 10A and the first electrode layer 13 of the second vibration part 10B by one first signal line 92a.

According to an aspect of the present disclosure, an end portion of the second signal line 92b may be disposed between the second cover member 50 and the second surface of the vibration generating part 10. For example, the end portion of the second signal line 92b may be configured to be electrically connected to the third auxiliary electrode layer 17 electrically disconnected from the uppermost electrode layer 13 of the vibration generating part 10. For example, the end portion of the second signal line 92b electrically connected to the third auxiliary electrode layer 17 of the vibration generating part 10 may be covered by the adhesive layer 40 or the second adhesive layer 42, but aspects of the present disclosure are not limited thereto. For example, the end portion of the second signal line 92b electrically connected to the third auxiliary electrode layer 17 of the vibration generating part 10 may not be covered by the adhesive layer 40 or the second adhesive layer 42 and may contact or directly contact the second cover member 50.

The end portion of the second signal line 92b may be electrically connected (or contact) to the third auxiliary electrode layer 17 electrically disconnected from the uppermost electrode layer 13 of the vibration generating part 10. For example, the end portion of the second signal line 92b may be configured to be electrically connected to at least a portion of the third auxiliary electrode layer 17. For example, the second signal line 92b may be electrically connected to the second electrode layer 15 of the first vibration part 10A through the third auxiliary electrode layer 17, the third contact hole CNT3 and the second electrode layer 15 of the second vibration part 10B, and the connection layer 20. For example, the second signal line 92b may be connected to the second electrode layer 15 of the second vibration part 10B and the second electrode layer 15 of the first vibration part 10A through the third auxiliary electrode layer 17. The signal applied to the second signal line 92b may be supplied to the second electrode layer 15 of the first vibration part 10A through the third auxiliary electrode layer 17, the third contact hole CNT3 and the second electrode layer 15 of the second vibration part 10B, and the connection layer 20. Therefore, the second signal line 92b may transfer the driving signal, supplied from the vibration driving circuit, to the first electrode layer 13 of the second vibration part 10B and the first electrode layer 13 of the first vibration part 10A in common. Accordingly, two separate signal lines respectively connected to the second electrode layer 15 of the first vibration part 10A and the second electrode layer 15 of the second vibration part 10B may not be provided, and the same signal may be applied to the second electrode layer 15 of the first vibration part 10A and the second electrode layer 15 of the second vibration part 10B by using one second signal line 92b.

In the first vibration part 10A, the first electrode layer 13 may receive the driving signal through the first signal line 92a, and the second electrode layer 15 may receive the driving signal through the second signal line 92b. Accordingly, the first vibration part 10A may alternately repeat contraction and/or expansion, based on an inverse piezoelectric effect which is generated from the driving signal by the vibration layer 11, and thus, may vibrate (or displace or drive).

In the second vibration part 10B, the first electrode layer 13 may receive the driving signal through the first signal line 92a, and the second electrode layer 15 may receive the driving signal through the second signal line 92b. Accordingly, the second vibration part 10B may alternately repeat contraction and/or expansion, based on an inverse piezoelectric effect which is generated from the driving signal by the vibration layer 11, and thus, may vibrate (or displace or drive).

Each of the first vibration part 10A and the second vibration part 10B may be flexed (or displaced or driven) in the same shape. Therefore, in the vibration generating part 10 or the vibration apparatus, a vibration width (or a displacement width or a driving width) of the first vibration part 10A and a vibration width (or a displacement width or a driving width) of the second vibration part 10B may be summated and maximized. For example, in the vibration generating part 10 or the vibration apparatus, a vibration of the first vibration part 10A and a vibration of the second vibration part 10B may be reinforced, and thus, vibration efficiency or vibration characteristic may be enhanced and a vibration width (or a displacement width or a driving width) of the second vibration part 10B may be maximized, whereby a sound characteristic and/or a sound pressure level characteristic of a low-pitched sound band may be enhanced.

The signal cable 90 may include first and second extension portions 91a and 91b which respectively support the end portions (or distal end portions or one side) of the first and second signal lines 92a and 92b apart from one another. For example, each of the first and second extension portions 91a and 91b may be apart from one another between one edge portion of the first cover member 30 and one edge portion of the second cover member 50. Accordingly, the end portions (or distal end portions) of the first and second signal lines 92a and 92b may be apart from one another, and thus, may be individually bent or curved.

According to another aspect of the present disclosure, each of the first and second extension portions 91a and 91b of the signal cable 90 may be omitted. For example, each of the first and second signal lines 92a and 92b may protrude or extend in a finger shape from the base member 91 and may be electrically connected to or contact corresponding electrode layers 13 and 15, between the one edge portion of the first cover member 30 and the one edge portion of the second cover member 50. For example, the end portions (or distal end portions or one side) of the first and second signal lines 92a and 92b may be electrically connected to or contact the corresponding electrode layers 13 and 15 by a conductive double-sided tape, and thus, an adhesive force to the corresponding electrode layers 13 and 15 may be secured.

The signal cable 90 according to an example aspect of the present disclosure may further include an insulation member 93.

The insulation member 93 may be disposed at the first surface of the base member 91 to cover each of the first to third signal lines 92a to 92c other than the end portion of the signal cable 90. The insulation member 93 may be a protection layer, a coverlay, a coverlay layer, a cover film, an insulation film, or a solder mask, but aspects of the present disclosure are not limited thereto.

The end portion (or distal end portion or one side) of the signal cable 90 inserted (or accommodated) between the first cover member 30 and the second cover member 50 may be inserted (or accommodated) and fixed between the first cover member 30 and the second cover member 50 through a film laminating process which uses the first adhesive layer 41 formed in the first cover member 30 and the second adhesive layer 42 formed in the second cover member 50. Therefore, the first signal line 92a may be maintained with being electrically connected to the first electrode layer 13 of the second vibration part 10B. Therefore, the second signal line 92b may be maintained with being electrically connected to the second electrode layer 15 of the first vibration part 10A and the second electrode layer 15 of the second vibration part 10B through the third auxiliary electrode layer 17.

Moreover, the end portion (or distal end portion or one side) of the signal cable 90 may be inserted (or accommodated) and fixed between the first cover member 30 and the second cover member 50, and thus, a connection defect between the vibration generating part 10 and the signal cable 90 caused by the movement of the signal cable 90 may be prevented.

In the vibration apparatus according to an aspect of the present disclosure, the first and second signal lines 92a and 92b of the signal cable 90 may be connected to the electrode layer of the vibration generating part 10 between the first cover member 30 and the second cover member 50, and thus, a soldering process for an electrical connection between the vibration generating part 10 and the signal cable 90 may not be needed, thereby simplifying a structure and a manufacturing process of a vibration apparatus. Also, the vibration apparatus according to another aspect of the present disclosure may include the plurality of vibration parts 10A and 10b which overlap or overlay each other to vibrate (or displace or drive) in the same direction, and thus, vibration efficiency or vibration characteristic may be enhanced and a vibration width (or a displacement width or a driving width) may be maximized, thereby enhancing a sound characteristic and/or a sound pressure level characteristic of a pitched sound band including the low-pitched sound band.

Moreover, in the vibration apparatus according to an aspect of the present disclosure, all of the first and second signal lines 92a and 92b of the signal cable 90 may be provided between the second cover member 50 and vibration generating part 10. Therefore, in the vibration apparatus according to an aspect of the present disclosure, the signal lines may not be provided between the plurality of vibration parts 10A and 10B, and thus, a thickness of the vibration apparatus may decrease and a step height caused by the signal lines may decrease. Also, in the vibration apparatus according to an aspect of the present disclosure, a crack may be prevented from occurring in bonding or attaching the first cover member 30 to the second cover member 50 due to a step height which occurs when connecting signal lines. For example, in the vibration apparatus according to an aspect of the present disclosure, all of the first and second signal lines 92a and 92b may be provided on the upper surface of the vibration generating part 10, and thus, in a case where a signal line is provided between the first vibration part 10A and the second vibration part 10B, the occurrence of a defect such as a crack caused by bonding between the first vibration part 10A and the second vibration part 10B may be prevented.

Moreover, in the vibration apparatus according to an aspect of the present disclosure, the connection layer 20 and the auxiliary connection layer 23 may be configured between the first vibration part 10A and the second vibration part 10B, and the connection layer 20 and the auxiliary connection layer 23 may include a glass frit including Ag, thereby enhancing an adhesive force between the first vibration part 10A and the second vibration part 10B. For example, in an aspect of the present disclosure, the electrode layers 13 to 17 may include Ag including a glass frit, and the connection layer 20 may include a glass frit including Ag. For example, in the electrode layers 13 to 17, a content of Ag may be far higher than a content of glass frit, to secure high conductivity. For example, in the connection layer 20, a content of glass frit may be higher than a content of Ag, to secure all of conductivity and an adhesive force.

According to an aspect of the present disclosure, the connection layer 20 may include a glass frit, and thus, may further enhance an adhesive force between the second electrode layer 15 of the first vibration part 10A and the second electrode layer 15 of the second vibration part 10B. Also, the connection layer 20 may include Ag, and thus, may electrically connect the second electrode layer 15 of the first vibration part 10A, configured at a first surface (or a lower surface) of the connection layer 20, to the second electrode layer 15 of the second vibration part 10B configured at a second surface (or an upper surface) of the connection layer 20. Also, the connection layer 20 may include a glass frit including Ag, and thus, comparing with a case where the connection layer 20 is not provided, the second electrode layer 15 of the first vibration part 10A and the second electrode layer 15 of the second vibration part 10B facing each other may be attached on each other, and moreover, the occurrence of a crack in the vibration generating part 10 may be prevented by attachment.

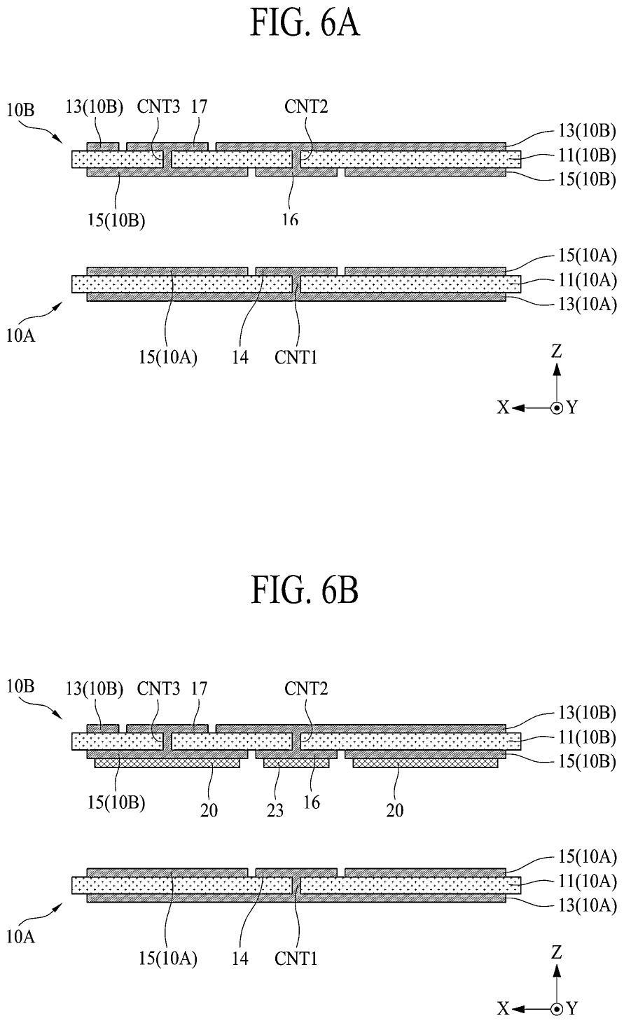

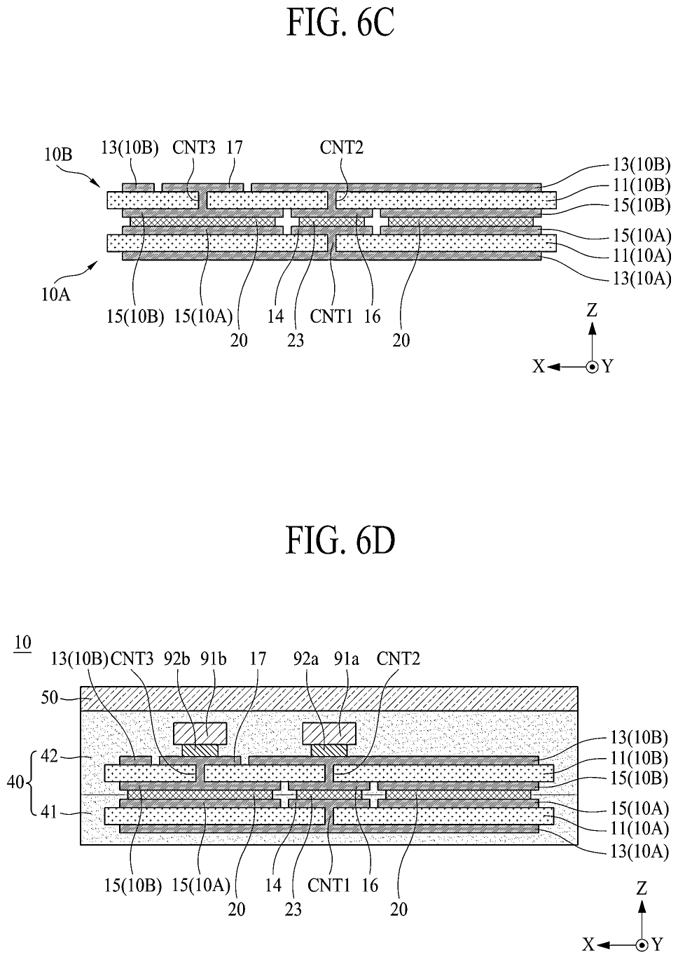

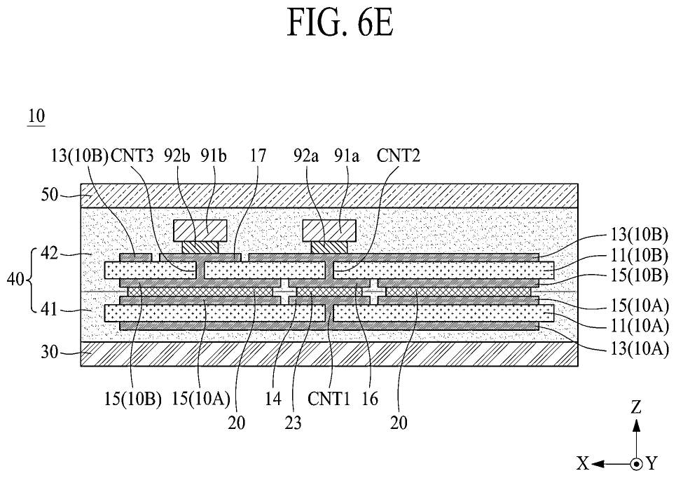

FIGS. 6A to 6E illustrate a method of manufacturing a vibration apparatus according to an aspect of the present disclosure. FIGS. 6A to 6E illustrate a method of manufacturing a vibration apparatus according to an aspect of the present disclosure of FIGS. 1 to 5. Hereinafter, therefore, the same elements will be assigned the same symbols, and the redundant explanations will be briefly described or omitted.

Referring to FIGS. 6A to 6E, a method of manufacturing a vibration apparatus according to an aspect of the present disclosure may include a step of forming a plurality of vibration parts 10A and 10B, a step of forming a connection layer 20 in one of the plurality of vibration parts 10A and 10B, a step of attaching the plurality of vibration parts 10A and 10B on each other, and a step of connecting a signal line and forming a first cover member 30 and a second cover member 50.

Referring to FIG. 6A, the step of forming the plurality of vibration parts 10A and 10B may include a step of forming a vibration layer 11. For example, the vibration layer 11 may include a piezoelectric material (or an electro active material) including a piezoelectric effect. For example, the vibration layer 11 may be configured to have a width of 6 cm, a height of 12 cm, and a thickness of 165 μm, but aspects of the present disclosure are not limited thereto.

Subsequently, a first contact hole CNT1 may be formed in a vibration layer 11 of the first vibration part 10A, and a second contact hole CNT2 and a third contact hole CNT3 may be formed in a vibration layer 11 of the second vibration part 10B. For example, the first contact hole CNT1 may be formed in one end (or one side) of each vibration layer 11 to face the second contact hole CNT2. For example, the second contact hole CNT2 may be spaced apart from the third contact hole CNT3 by a certain distance. For example, the third contact hole CNT3 may be formed in the other end (or the other side) of the vibration layer 11 of the second vibration part 10B to be spaced apart from the second contact hole CNT2.

Subsequently, a second electrode layer 13 may be formed at a first surface (or a lower surface) of the vibration layer 11 of the first vibration part 10A, and a second electrode layer 15 and a first auxiliary electrode layer 14 may be formed at a second surface (or an upper surface) of the vibration layer 11 of the first vibration part 10A. Here, the first electrode layer 13 may be connected to the first auxiliary electrode layer 14 through the first contact hole CNT1.

Subsequently, a second electrode layer 15 and a second auxiliary electrode layer 16 may be formed at a first surface (or a lower surface) of the vibration layer 11 of the second vibration part 10B, and a first electrode layer 13 and a third auxiliary electrode layer 17 may be formed at a second surface (or an upper surface) of the vibration layer 11 of the second vibration part 10B. For example, the first electrode layer 13 may be connected to the second auxiliary electrode layer 16 through the second contact hole CNT2. For example, the second electrode layer 15 may be connected to the third auxiliary electrode layer 17 through the third contact hole CNT3.

According to an aspect of the present disclosure, a metal paste including Ag may be coated on a region, where an electrode layer is to be disposed, of each of a first surface and a second surface of the vibration layer 11 and may then be fired, thereby forming each of the first electrode layer 13, the second electrode layer 15, the first auxiliary electrode layer 14, the second auxiliary electrode layer 16, and the third auxiliary electrode layer 17. For example, firing may be performed for about 15 minutes at a temperature of 650° C. to 700° C., but aspects of the present disclosure are not limited thereto. For example, after firing is maintained for about 15 minutes at a temperature of 650° C. to 700° C., a natural cooling process may be performed, but aspects of the present disclosure are not limited thereto. A process time may include a thermal treatment time and a natural cooling time and may be about one hour, but embodiments of the present disclosure are not limited thereto. For example, the metal paste including Ag may be formed to have a thickness of about 5 μm or less, but aspects of the present disclosure are not limited thereto.

Referring to FIG. 6B, the step of forming the connection layer 20 in one of the plurality of vibration parts 10A and 10B may be a step of forming the connection layer 20 and an auxiliary connection layer 23 at a first surface (or a lower surface) of the second vibration part 10B. The connection layer 20 may be formed by coating and drying a material, used as the connection layer 20, on a first surface (or a lower surface) of a second electrode layer 15 of the second vibration part 10B. The auxiliary connection layer 23 may be formed by coating and drying a material, used as the auxiliary connection layer 23, on a first surface (or a lower surface) of a second auxiliary electrode layer 16. For example, drying may be performed for 5 minutes to 15 minutes within a temperature range of 120° C. to 160° C., but aspects of the present disclosure are not limited thereto. For example, drying may be performed for 10 minutes at 150° C., but aspects of the present disclosure are not limited thereto. For example, the connection layer 20 and the auxiliary connection layer 23 may include the same material and may be formed by using the same process, but aspects of the present disclosure are not limited thereto. For example, the connection layer 20 and the auxiliary connection layer 23 may include Ag of 20 wt % or less. For example, a content of Ag of each of the connection layer 20 and the auxiliary connection layer 23 may be 20 wt % or less, based on conductivity and an adhesive force. Therefore, the connection layer 20 and the auxiliary connection layer 23 may have conductivity. For example, the connection layer 20 and the auxiliary connection layer 23 may include a glass frit of 50 wt % to 70 wt %. Therefore, the connection layer 20 and the auxiliary connection layer 23 may have conductivity and may also have an adhesive force. For example, each of the connection layer 20 and the auxiliary connection layer 23 may have a thickness of 10 μm or less, but aspects of the present disclosure are not limited thereto.

Subsequently, the method may further include a process of removing an organic material in the connection layer 20 and the auxiliary connection layer 23. For example, the process of removing the organic material in the connection layer 20 and the auxiliary connection layer 23 may be a plasticizing process, a primary firing process, or a primary thermal treatment process. For example, the plasticizing process may be performed for 1 hour to 2 hours within a temperature range of 400° C. to 450° C., but aspects of the present disclosure are not limited thereto. For example, the plasticizing process may be omitted.

According to an aspect of the present disclosure, the connection layer 20 and the auxiliary connection layer 23 may use a cellulose-based binder. The cellulose-based binder may be volatilized at a temperature of about 400° C. For example, all or the most of the binder included in the connection layer 20 and the auxiliary connection layer 23 may be volatilized in a plasticizing step. Therefore, a secondary firing process described below, an air bubble or a pore such as a void may be minimized in the connection layer 20 and the auxiliary connection layer 23. Accordingly, the thin film uniformity of each of the connection layer 20 and the auxiliary connection layer 23 may be enhanced.

Referring to FIG. 6C, the method may include a step of attaching (or adhering) the plurality of vibration parts 10A and 10B. First, the first vibration part 10A and the second vibration part 10B may be disposed to face each other and may be attached by alignment. Here, the connection layer 20 and the auxiliary connection layer 23 may be configured between the first vibration part 10A and the second vibration part 10B.

Subsequently, a load of about 0.2 kg or more may be applied to an upper surface of the second vibration part 10B, and thermal treatment may be performed on the connection layer 20 and the auxiliary connection layer 23 at a high temperature, but aspects of the present disclosure are not limited thereto. A process of performing thermal treatment on the connection layer 20 and the auxiliary connection layer 23 at a high temperature may be a firing step. For example, the firing step may be a secondary firing process or a secondary thermal treatment process. For example, the firing step may be a step of melting the glass frit coated (or applied) on the electrode layer 13. For example, a glass transition temperature Ts of the glass frit used as the connection layer 20 and the auxiliary connection layer 23 may be about 350° C. to 550° C. Therefore, the secondary firing process may be performed for about 1 hour to 2 hours at a temperature of 650° C. to 750° C., but aspects of the present disclosure are not limited thereto. For example, the secondary firing process may be performed for about 1 hour at a temperature of 650° C., but aspects of the present disclosure are not limited thereto. A melted glass frit may include a uniform surface and may be cooled at a room temperature, and thus, may be solidified to configure the connection layer 20 and the auxiliary connection layer 23. Therefore, the first vibration part 10A and the second vibration part 10B may be easily connected to each other. Accordingly, the first vibration part 10A and the second vibration part 10B may be easily attached on each other.

Additionally, a firing temperature of the vibration layer 11 may be 650° C. or more, and thus, a content of glass frit may not be changed based on a change in the vibration layer 11.

Referring to FIG. 6D, the method may include a step of placing a signal line in the vibration generating part 10 and attaching a second cover member (or a protection member) 50 thereon. For example, the step of placing the signal line in the vibration generating part 10 and attaching the second cover member 50 thereon may be a process of placing a first signal line 92a on a first electrode layer 13 of the second vibration part 10B, placing a second signal line 92b on a third auxiliary electrode layer 17, and attaching the second cover member 50 on a first surface of the vibration generating part 10 by using a laminating process which uses a second adhesive layer 42. Accordingly, the first signal line 92a may be electrically connected (or contact) to the first electrode layer 13 of the second vibration part 10B, and the second signal line 92b may be electrically connected (or contact) to the third auxiliary electrode layer 17.

Moreover, the method may include a step of forming (or coating) a first adhesive layer 41 at a first surface of the vibration generating part 10. Therefore, the vibration generating part 10 may be surrounded by the second cover member 50 and the first adhesive layer 41. For example, the vibration generating part 10 may be surrounded by the first adhesive layer 41 and the second adhesive layer 42, or may be buried (or accommodated) into an adhesive layer 40 including the first adhesive layer 41 and the second adhesive layer 42.

Referring to FIG. 6E, the method may further include a step of attaching a first cover member 30 on the first surface of the vibration generating part 10. The first cover member 30 may be connected or coupled to the first surface of the vibration generating part 10 by using a laminating processing which uses the first adhesive layer 41. Therefore, the vibration generating part 10 may be disposed between the first cover member 30 and the second cover member 50. For example, the vibration generating part 10 may be surrounded by the first adhesive layer 41 and the second adhesive layer 42, or may be buried (or accommodated) into the adhesive layer 40 including the first adhesive layer 41 and the second adhesive layer 42.

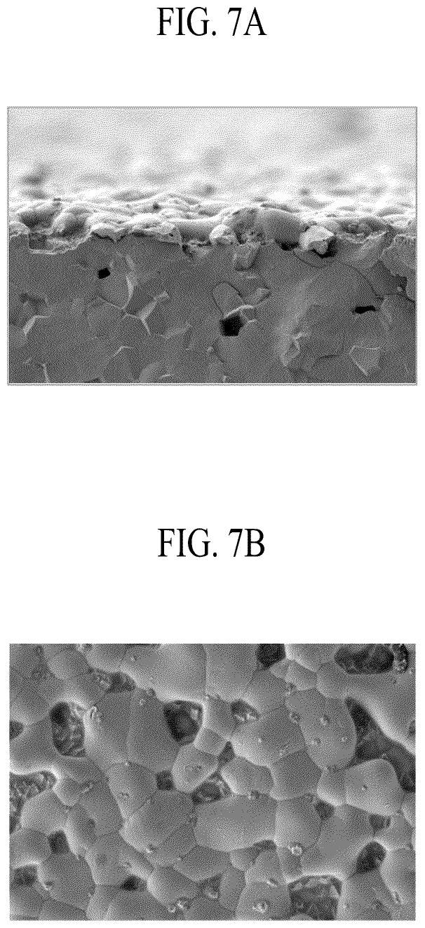

FIGS. 7A and 7B illustrates a cross-sectional surface image and a surface image of an electrode layer according to an experiment example 1.

The inventors have prepared a sample as an experiment example 1, to review a surface image and a cross-sectional surface image of an electrode layer where a connection layer according to an aspect of the present disclosure is not configured. In the experiment example 1, the electrode layer has been configured at an upper surface of a vibration layer. The electrode layer of the experiment example 1 has been configured by coating (or applying), drying, and firing an Ag paste and a glass frit of about 8 wt %. Firing has been maintained for about 15 minutes at a temperature of 650° C. to 700° C., and then, has been naturally cooled. An experiment content of the electrode layer of the experiment example 1 does not limit the details of the present disclosure.

Referring to FIG. 7A, it may be seen that a surface of a sample where only an electrode layer is formed is not uniform and includes a rough surface. Referring to FIG. 7B, it may be seen that an electrode layer has a thickness of about 2 μm, in a surface of a sample where only the electrode layer is formed.

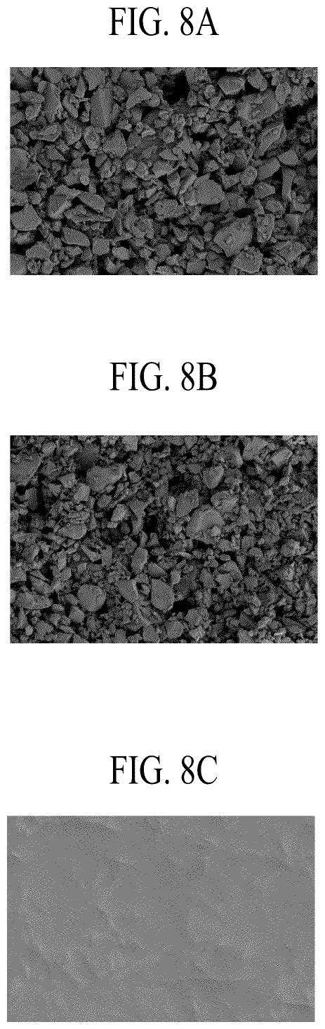

FIGS. 8A to 8C illustrate a surface image of a connection layer according to an aspect of the present disclosure. FIGS. 8A to 8C illustrate a surface changes of a connection layer according to a process of firing. FIG. 8A illustrates an image after a connection layer is coated and dried, FIG. 8B illustrates an image after the connection layer is primarily fired, and FIG. 8C illustrates an image after the connection layer is secondarily fired.

The inventors have prepared a sample as an aspect 1, to review a surface image and a cross-sectional surface image of a vibration part including the connection layer according to an aspect of the present disclosure.

The aspect 1 represents a surface change according to a process of coating a vibration layer on the connection layer and firing a coated vibration layer and is an aspect where the connection layer is configured at an upper surface of the vibration layer. In the aspect 1, the connection layer has been configured to include a glass frit of 50 wt % to 70 wt % and an Ag paste of 20 wt % or less. In the aspect 1, the connection layer has been configured by sequentially performing a step of coating (or applying) the glass frit of 50 wt % to 70 wt % and the Ag paste of 20 wt % or less on the electrode layer and drying the coated glass frit and Ag paste, a primary firing (or plasticizing) step, and a secondary firing (or plasticizing) step. For example, the connection layer has been configured by coating a material, including the glass frit of 50 wt % to 70 wt % and the Ag paste of 20 wt % or less, on the vibration layer, drying a coated material for 10 minutes at 150° C., primarily firing a dried connection layer for 1 hour at 400° C., and secondarily firing a primarily-fired connection layer for 1 hour at 650° C. An experiment content of the electrode layer of the experiment example 1 does not limit the details of the present disclosure.

Referring to FIG. 8A, it may be seen that a surface shape of a connection layer is maintained in a process where a solvent of the connection layer is volatilized. For example, after the glass frit of 50 wt % to 70 wt % and the Ag paste of 20 wt % or less are coated (or applied) on the vibration layer, a drying process may be performed for volatilizing the solvent of the connection layer. According to an aspect of the present disclosure, it may be seen that the surface of the connection layer is not damaged in a drying process of volatilizing the solvent of the connection layer.

Referring to FIG. 8B, it may be seen that the surface shape of the connection layer is maintained similar to a drying step in a process where an organic material is volatilized. For example, primary firing may be performed for volatilizing the organic material of the connection layer. According to an aspect of the present disclosure, it may be seen that the surface of the connection layer is not damaged and is maintained while undergoing a primary firing step.

Referring to FIG. 8C, secondary firing is a step of melting the connection layer, and it may be seen that a glass frit used as the connection layer is melted, and thus, a thin film including a uniform surface is formed.

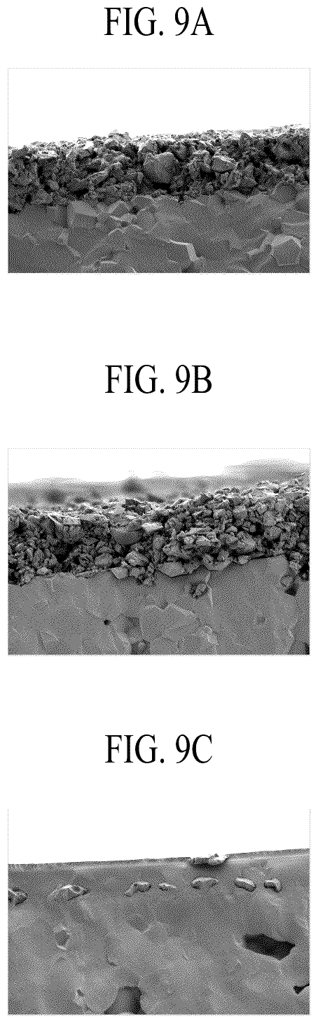

FIGS. 9A to 9C illustrate a cross-sectional surface image of each of a vibration layer, an electrode layer, and a connection layer according to an aspect of the present disclosure. FIG. 9A illustrates an image after a connection layer is coated and dried, FIG. 9B illustrates an image after primary firing, and FIG. 9C illustrates an image after secondary firing.

The inventors have prepared a sample as an aspect 2, to review a cross-sectional surface image of a vibration part including the connection layer according to an aspect of the present disclosure.

The aspect 2 represents a cross-sectional surface change of each of a vibration layer, an electrode layer, and a connection layer based on a process of coating the connection layer on the vibration layer and firing a coated connection layer and is an aspect where the connection layer is configured at an upper surface of the electrode layer and the vibration layer.

In the aspect 2, the electrode layer has been configured to be equal to the electrode layer described above with reference to FIGS. 7A and 7B. For example, in the aspect 2, the electrode layer has been configured by coating (or applying) and drying an Ag paste and a glass frit of about 8 wt %.

In the aspect 2, the connection layer has been configured to include a glass frit of 50 wt % to 70 wt % and an Ag paste of 20 wt % or less. In the aspect 2, the connection layer has been configured by sequentially performing a step of coating (or applying) the glass frit of 50 wt % to 70 wt % and the Ag paste of 20 wt % or less on the electrode layer and drying the coated glass frit and Ag paste, a primary firing (or plasticizing) step, and a secondary firing (or plasticizing) step. For example, the connection layer has been configured by coating a material, including the glass frit of 50 wt % to 70 wt % and the Ag paste of 20 wt % or less, on the vibration layer, drying a coated material for 10 minutes at 150° C., primarily firing a dried connection layer for 1 hour at 400° C., and secondarily firing a primarily-fired connection layer for 1 hour at 650° C. An experiment content of the electrode layer of the experiment example 2 does not limit the details of the present disclosure.

Referring to FIGS. 9A to 9C, it may be seen that a thickness of the connection layer is reduced as an organic material is volatilized while undergoing drying and a primary firing step. In each of FIGS. 9A and 9B, it has been measured that a thickness of the connection layer is about 7.8 μm after drying the glass frit, and a thickness of the connection layer is about 6.5 μm after primary firing. Accordingly, it may be seen that, as a primary firing process is performed, the organic material is volatilized and a thickness of the glass frit is reduced. Also, in FIG. 9C, it may be seen that the connection layer is configured on the vibration layer after secondary firing is performed.

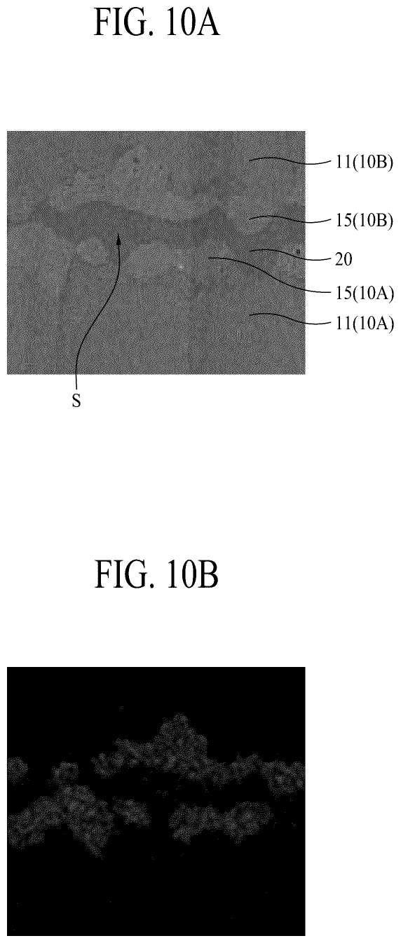

FIGS. 10A and 10B illustrate a cross-sectional surface image of a vibration generating part according to an aspect of the present disclosure. In FIG. 10B, bright parts represent that Ag is provided.

The inventors have prepared a sample as an embodiment 3, to review an adhesive force of the connection layer according to an aspect of the present disclosure and that Ag is included in the connection layer.

In the aspect 3, a vibration generating part has been configured as in FIGS. 6A to 6C, and a sample has been prepared by forming each of a first vibration layer and a second vibration layer, forming a connection layer on a lower surface of the second vibration layer, and bonding the first vibration layer to the second vibration layer with the connection layer therebetween. An electrode layer of the aspect 3 includes a glass frit of about 8 wt % and an Ag paste of about 50 wt % to 80 wt %, and a connection layer includes a glass frit of about 50 wt % to 70 wt % and an Ag paste of 20 wt % or less. An experiment content of the electrode layer of the experiment example 3 does not limit the details of the present disclosure.

Referring to FIGS. 10A and 10B, it may be seen that a first vibration part 10A and a second vibration part 10B are easily bonded to each other without being partially detached. Also, it may be seen that Ag is included in all of an electrode layer 15 and a connection layer 20. For example, the inventors have measured a spectrum in a certain measurement region S, to check that Ag is included in the connection layer 20. Accordingly, according to an aspect of the present disclosure, it may be seen that the connection layer includes a glass frit and thus is good in adhesive force, and the connection layer includes Ag and thus has conductivity.

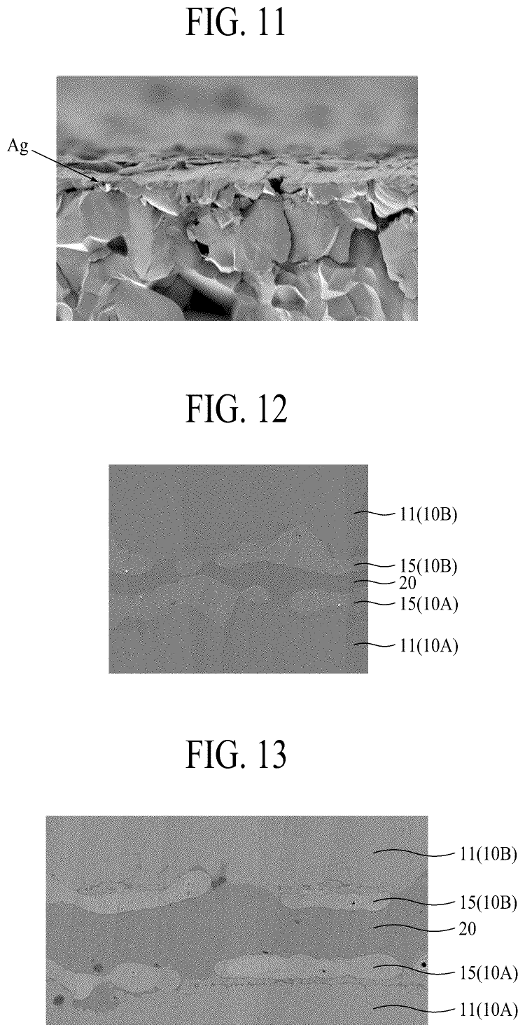

FIG. 11 illustrates a cross-sectional surface image of an electrode layer according to an experiment example 2.

The inventors have prepared a sample as an experiment example 2, to review a shape of an electrode layer in a case where attachment and thermal treatment are performed in a state where a connection layer is not configured.

In the experiment example 2, a first vibration part and a second vibration part have been formed, the first vibration part and the second vibration part have been disposed to face each other, and a load has been applied thereto, and thus, the sample has been prepared. In the experiment example 2, the electrode layer includes Ag of 50 wt % and a glass frit of 8 wt %. An experiment content of the electrode layer of the experiment example 2 does not limit the details of the present disclosure.

Referring to FIG. 11, in a case where the first vibration part and the second vibration part are configured without a connection layer, it may be seen that a cross-sectional surface of the electrode layer is not uniform, and a fine crack occurs in a vertical direction in the cross-sectional surface of the electrode layer.

Moreover, in a sampling step for scanning electron microscope (SEM) analysis, the first vibration part and the second vibration part have been separated from each other due to breaking caused by a low interface adhesive force. Therefore, only an interface of a separated single vibration layer may be measured. Also, in a case where a connection layer is not provided, it may be seen that a crack and partial detachment occur between the first vibration part and the second vibration part, in an outer region of a vibration generating part. Accordingly, in a case where a connection layer is not provided, it may be seen that an interface adhesive force between the first vibration part and the second vibration part is very low.

FIGS. 12 and 13 are diagrams for describing a cross-sectional surface of a vibration part based on a content of glass frit according to an aspect of the present disclosure. FIG. 12 illustrates a cross-sectional surface of a vibration generating part including a connection layer including a glass frit of 50 wt %, and FIG. 13 illustrates a cross-sectional surface of a vibration generating part including a connection layer including a glass frit of 70 wt %.

Referring to FIG. 12, when a content of glass frit in a connection layer 20 is 50 wt %, a vibration generating part may have a structure where a second electrode layer 15 of a first vibration part 10A and a second electrode layer 15 of a second vibration part 10B adhered to each other by the connection layer 20 are partially provided in the connection layer 20. For example, when a content of glass frit in the connection layer 20 is 50 wt %, a distance between the second electrode layer 15 of the first vibration part 10A and the second electrode layer 15 of the second vibration part 10B may be short, and thus, the vibration generating part may have a structure where the second electrode layer 15 is partially provided in the connection layer 20. Therefore, an electrical connection between interfaces between the second electrode layer 15 of the first vibration part 10A and the second electrode layer 15 of the second vibration part 10B may be more easily performed. For example, the connection layer 20 represents an average thickness of about 1.8 μm, and it may be seen that an adhesive force is good. Accordingly, when a fine pattern structure is applied, it may be seen that the electrical connection between the interfaces between the second electrode layer 15 of the first vibration part 10A and the second electrode layer 15 of the second vibration part 10B is more easily performed. Here, a fine pattern structure may be a structure including the first to third auxiliary electrode layers 14, 16, and 17 described above with reference to FIGS. 1 to 5. For example, a fine pattern may be the first to third auxiliary electrode layers 14, 16, and 17.

For example, when a content of glass frit in the connection layer 20 is 50 wt %, an electrical connection between interfaces between the connection layer 20, the second electrode layer 15 of the first vibration part 10A, and the second electrode layer 15 of the second vibration part 10B may be more easily performed in the fine pattern structure, and thus, an area of a third auxiliary electrode layer connected to a second signal line may be reduced. For example, in a case where a vibration generating part having a stack structure is configured, configurations of first to third auxiliary electrode layers and first to third contact holes may be needed. In this case, the conductivity of the connection layer 20 and an auxiliary connection layer 23 may be good, and thus, an area of the first to third auxiliary electrode layers may be reduced.

Referring to FIG. 13, when a content of glass frit in a connection layer 20 is 70 wt %, a vibration generating part may have a structure where a second electrode layer 15 of a first vibration part 10A and a second electrode layer 15 of a second vibration part 10B adhered to each other by the connection layer 20 are separated from the connection layer 20. For example, when a content of glass frit in the connection layer 20 is 70 wt %, a distance between the second electrode layer 15 of the first vibration part 10A and the second electrode layer 15 of the second vibration part 10B may be long, and thus, the second electrode layer 15 is easily separated from the connection layer 20. Accordingly, the degree of electrical connection between the second electrode layer 15 of the first vibration part 10A and the second electrode layer 15 of the second vibration part 10B is lower than a case where a content of glass frit in the connection layer 20 is 50 wt %. However, it may be seen that the connection layer 20 has an average thickness of about 3 μm to 4 μm, and it may be seen that an adhesive force is better than a case where a content of glass frit is 50 wt %. Accordingly, when a content of glass frit is 70 wt %, it may be seen that the connection layer 20 is applicable to the product group requiring the verification of relatively higher adhesive force and reliability.

Referring to FIGS. 12 and 13, it may be seen that, as a content of glass frit increases, a thickness of a connection layer increases, and the glass frit is easily separated from an Ag electrode. Accordingly, in an aspect of the present disclosure, a thickness of glass frit and a separation level with respect to an Ag electrode may be easily changed by adjusting a content of glass frit.

The following Table 1 shows a linear resistance with respect to a content of glass frit. A sample has been prepared according to FIGS. 12 and 13, and the linear resistance has been measured by using a multi-miter in the same distance (for example, 12 cm).

TABLE 1

| Content of Glass Frit (wt %) | 50 wt % | 70 wt % |
|---|---|---|
| Linear Resistance (Ω) | <0.2 | <0.2 |

Referring to Table 1, when a content of glass frit is 50 wt % and 70 wt %, all linear resistances have been measured to be 0.2Ω or less. Therefore, it may be seen that a structure of a vibration apparatus is more simplified as the connection layer 20 is configured, in a stack structure of a first vibration part 10A and a second vibration part 10B.

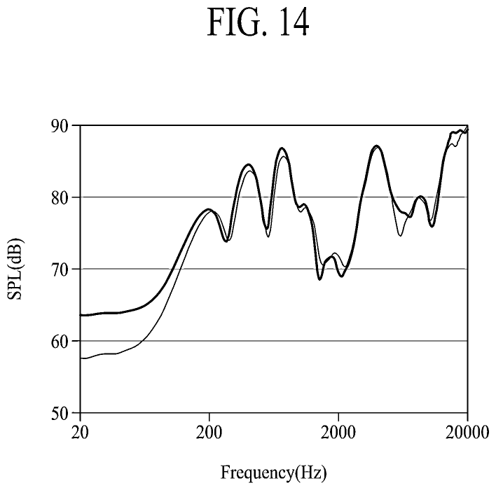

FIG. 14 is a graph showing a sound pressure level characteristic according to an aspect of the present disclosure and the experiment example 2. FIG. 14 is a graph showing a sound pressure level characteristic according to an aspect of the present disclosure and the experiment example 2. In FIG. 14, the abscissa axis represents a frequency Hz (hertz), and the ordinate axis represents a sound pressure level (SPL) dB (decibel). In FIG. 14, a thin solid line represents a sound pressure level characteristic with respect to a frequency in the experiment example 2, and a thick solid line represents a sound pressure level characteristic with respect to a frequency in the aspect 3.

The inventors have prepared the experiment example 2 and the aspect 3, to compare a sound pressure level characteristic of a vibration apparatus according to an aspect of the present disclosure.

A vibration apparatus according to the experiment example 2 has been prepared equal to the experiment example 2 described above with reference to FIG. 11, and in a vibration apparatus according to the aspect 3, a sample has been prepared based on a manufacturing method according to an aspect of the present disclosure described above with reference to FIGS. 6A to 6D. In the aspect 3, a content of glass frit has been set to 50 wt %. Hereinafter, therefore, descriptions of a sample manufacturing method of the experiment example 2 and a sample manufacturing method of the aspect 3 are omitted.

Referring to FIG. 14, a sound pressure level characteristic of the embodiment 3 is higher than that of the experiment example 2, within a frequency range of 20 Hz to 200 Hz, and as a frequency increases, a sound pressure level difference is reduced. It may be seen that a sound pressure level characteristic of the aspect 3 and a sound pressure level characteristic of the experiment example 2 have been measured to be equal to each other in 200 Hz or more.

The following Table 2 represents an evaluation result of each of the vibration apparatus of the aspect 3 and the vibration apparatus of the experiment example 2.

TABLE 2

| Evaluation Result | Experiment Example 2 | Aspect 3 |
|---|---|---|
| Cap. (μF) | 2.8 or more | 2.8 or more |
| Average Sound Pressure | 80 or more | 80 or more |
| Level | | |
| Reliability | OK | OK |
| Whether crack occurs or not, | Something | Nothing |
| in manufacturing of vibration | | |
| apparatus | | |

Referring to Table 2, as a result of test of each of the capacitance (Cap), average sound pressure level, and reliability of each of the experiment example 2 and the aspect 3, all characteristics of the vibration apparatuses of the experiment example 2 and the aspect 3 have been similarly measured to be 2.8 μF or more. For example, as a capacitance value increases, a vibration displacement of a vibration layer may more increase with respect to the same driving voltage. For example, the vibration displacement of the vibration layer may be proportional to a sound pressure level characteristic. For example, as a displacement of a vibration layer increases, a sound pressure level of a vibration apparatus may increase. For example, a capacitance value may be determined by an electrode layer and a connection layer. Here, a content of Ag and glass frit of each of the electrode layer and the connection layer may be an important factor. According to an aspect of the present disclosure, in the electrode layer, a content of Ag may be set to 50 wt % to 80 wt % and a content of glass frit may be set to 1 wt % to 12 wt %, and in the connection layer, a content of Ag may be set to 20 wt % or less and a content of glass frit may be set to 50 wt % to 70 wt %, and thus, a capacitance value equal to the experiment example 2 may be implemented. Also, it may be seen that a crack occurs in an electrode layer in the middle of manufacturing a vibration device in the experiment example 2, and a crack does not occur in the aspect 3. In the experiment example 2 and the aspect 3, an average sound pressure level has been measured to be about 80 dB or more with respect to 15 Hz to 20 kHz. With respect to a temperature of 50° C. and relative humidity of 80%, reliability after 250 hours elapse has been measured, and the reliability of the experiment example 2 and the aspect 3 has been measured to be similar to each other. A measurement condition of reliability does not limit the details of the present disclosure.

Accordingly, comparing with the experiment example 2, it may be seen that an aspect of the present disclosure further enhances an adhesive force of each of a first vibration part and a second vibration part while maintaining a sound pressure level characteristic, and a crack does not occur in a vibration generating part.

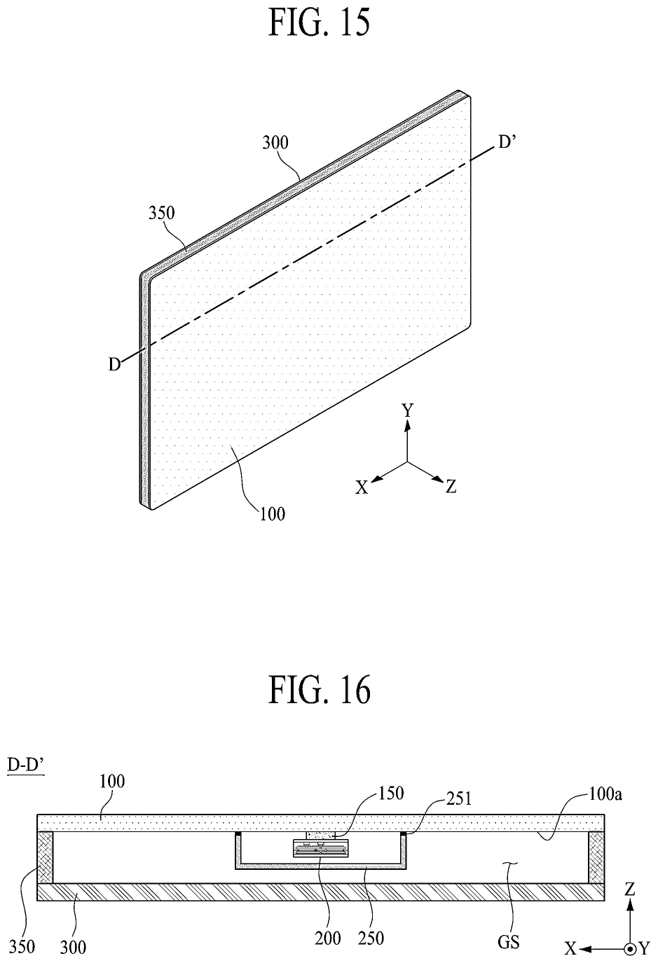

FIG. 15 illustrates an apparatus according to an aspect of the present disclosure. FIG. 16 is a cross-sectional view taken along line D-D′ illustrated in FIG. 15 according to an aspect of the present disclosure.

Referring to FIGS. 15 and 16, an apparatus according to an example aspect of the present disclosure may include a passive vibration member 100 and one or more vibration generating apparatuses 200.

The apparatus according to an example aspect of the present disclosure may be a display apparatus, a sound apparatus, a sound generating apparatus, a sound bar, an analog signage, or a digital signage, or the like, but aspects of the present disclosure are not limited thereto.

The display apparatus may include a display panel including a plurality of pixels which implement a black/white or color image and a driver configured to drive the display panel. An image according to an example aspect of the present disclosure may include an electronic image, a digital image, a still image, or a video image, but aspects of the present disclosure are not limited thereto. For example, the display panel may be an organic light emitting display panel, a light emitting diode display panel, an electrophoresis display panel, an electro-wetting display panel, a micro light emitting diode display panel, or a quantum dot light emitting display panel, or the like, but aspects of the present disclosure are not limited thereto. For example, in the organic light emitting display panel, a pixel may include an organic light emitting device such as an organic light emitting layer or the like, and the pixel may be a subpixel which implements any one of a plurality of colors configuring a color image. Therefore, an apparatus according to an example aspect of the present disclosure may include a set device (or a set apparatus) or a set electronic device such as a notebook computer, a television (TV), a computer monitor, an equipment apparatus including an automotive apparatus or another type apparatus for vehicles, or a mobile electronic device such as a smartphone, or an electronic pad, or the like which is a complete product (or a final product) including a display panel such as an organic light emitting display panel, a liquid crystal display panel, or the like.

The analog signage may be an advertising signboard, a poster, a noticeboard, or the like. The analog signage may include content such as a sentence, a picture, and a sign, or the like. The content may be disposed at the passive vibration member 100 of the apparatus to be visible. For example, the content may be directly attached on the passive vibration member 100 and the content may be printed or the like on a medium such as paper, and the medium may be attached on the passive vibration member 100.

The passive vibration member 100 may vibrate based on driving (or vibration) of the one or more vibration generating apparatuses 200. For example, the passive vibration member 100 may generate one or more of a vibration and a sound based on driving of the one or more vibration generating apparatuses 200.

The passive vibration member 100 according to an example aspect of the present disclosure may be a display panel including a display area (or a screen) having a plurality of pixels which implement a black/white or color image. Thus, the passive vibration member 100 may generate one or more of a vibration and a sound based on driving of the one or more vibration generating apparatuses 200. For example, the passive vibration member 100 may vibrate based on a vibration of the vibration generating apparatus 200 while a display area is displaying an image, and thus, may generate or output a sound synchronized with the image displayed on the display area. For example, the passive vibration member 100 according to an example aspect of the present disclosure may be a vibration object, a display member, a display panel, a signage panel, a passive vibration plate, a front cover, a front member, a vibration panel, a sound panel, a passive vibration panel, a sound output plate, a sound vibration plate, or a video screen, but aspects of the present disclosure are not limited thereto.

According to another example aspect of the present disclosure, the passive vibration member 100 may be a vibration plate including a metal material or a nonmetal material (or a complex nonmetal material), which has a material characteristic suitable for outputting a sound based on a vibration of each of the one or more vibration generating apparatuses 200. For example, the passive vibration member 100 may be a vibration plate including one or more materials of metal, plastic, paper, fiber, cloth, wood, leather, rubber, glass, carbon, and mirror. For example, the paper may be a cone paper for speakers. For example, the cone paper may be pulp or foam plastic, but aspects of the present disclosure are not limited thereto.

The passive vibration member 100 according to another example aspect of the present disclosure may include a display panel including a pixel displaying an image, or may include a non-display panel. For example, the passive vibration member 100 may include one or more of a display panel including a pixel configured to display an image, a screen panel on which an image is to be projected from a display apparatus, a lighting panel, a light emitting diode lighting panel, an organic light emitting lighting panel, an inorganic light emitting lighting panel, a signage panel, a vehicular interior material, a vehicular exterior material, a vehicular glass window, a vehicular seat interior material, a ceiling material of a building, an interior material of a building, a glass window of a building, an interior material of an aircraft, a glass window of an aircraft, and mirror, but aspects of the present disclosure are not limited thereto. For example, the non-display panel may be a light emitting diode lighting panel (or apparatus), an organic light emitting diode lighting panel (or apparatus), or an inorganic light emitting diode lighting panel (or apparatus), but aspects of the present disclosure are not limited thereto.

The one or more vibration generating apparatuses 200 may be configured to vibrate the passive vibration member 100. The one or more vibration generating apparatuses 200 may be configured to be connected to a rear surface 100a of the passive vibration member 100 by a connection member 150. Accordingly, the one or more vibration generating apparatuses 200 may vibrate the passive vibration member 100, and thus, may generate or output one or more of a vibration and a sound, based on a vibration of the passive vibration member 100.

The one or more vibration generating apparatuses 200 may include one or more of the vibration apparatuses described above with reference to FIGS. 1 to 14. Accordingly, the descriptions of the vibration apparatuses provided with reference to FIGS. 1 to 14 may be applicable to the vibration apparatuses illustrated with reference to FIGS. 15 and 16, and thus, like reference numerals may refer to like elements and repetitive descriptions thereof may be omitted.

The connection member 150 may be disposed between at least a portion of the vibration generating apparatus 200 and the passive vibration member 100. The connection member 150 may be connected between at least a portion of the vibration generating apparatus 200 and the passive vibration member 100. The connection member 150 according to an example aspect of the present disclosure may be connected between a center portion, except a periphery portion (or an edge portion), of the vibration generating apparatus 200 and the passive vibration member 100. For example, the connection member 150 may be connected between the center portion of the vibration generating apparatus 200 and the passive vibration member 100, based on a partial attachment scheme. The center portion (or a middle portion) of the vibration generating apparatus 200 may be a center of a vibration, and thus, a vibration of the vibration generating apparatus 200 may be efficiently transferred to the passive vibration member 100 through the connection member 150. The periphery portion (or the edge portion) of the vibration generating apparatus 200 may be in a state where the periphery portion (or the edge portion) of the vibration generating apparatus 200 is raised from each of the connection member 150 and the passive vibration member 100 without being connected to the connection member 150 and/or the passive vibration member 100, and thus, when a flexural vibration (or a bending vibration) of the vibration generating apparatus 200 is performed, a vibration of the edge portion of the vibration generating apparatus 200 may not be reduced (prevented) by the connection member 150 and/or the passive vibration member 100, and thus, a vibration width (or a displacement width or a driving width) of the vibration generating apparatus 200 may increase. Accordingly, a vibration width (or a displacement width or a driving width) of the passive vibration member 100 based on a vibration of the vibration generating apparatus 200 may increase, and thus, a sound characteristic and a sound pressure level characteristic of a low-pitched sound band generated based on a vibration of the passive vibration member 100 may be further enhanced.

According to another example aspect of the present disclosure, the connection member 150 may be connected to or attached on or at an entire front surface of the one or more vibration generating apparatuses 200 and the rear surface 100a of the passive vibration member 100, based on a front attachment scheme.

The connection member 150 according to an example aspect of the present disclosure may include a material including an adhesive layer which is good in adhesive force or attaching force with respect to the rear surface 100a of the passive vibration member 100 or the display panel and each of the one or more vibration generating apparatuses 200. For example, the connection member 150 may include a foam pad, a double-sided tape, an adhesive, or the like, but aspects of the present disclosure are not limited thereto. For example, an adhesive layer of the connection member 150 may include epoxy, acryl, silicone, or urethane, but aspects of the present disclosure are not limited thereto. For example, the adhesive layer of the connection member 150 may include an acryl-based material, having a characteristic where an adhesive force is relatively good and hardness is high, comparted to a urethane-based material. Accordingly, a vibration of each of the one or more vibration generating apparatuses 200 may be well transferred to the passive vibration member 100.

The apparatus according to an example aspect of the present disclosure may further include a supporting member 300 and a coupling member 350.

The supporting member 300 may be disposed at the rear surface 100a of the passive vibration member 100. The supporting member 300 may be disposed at the rear surface 100a of the passive vibration member 100 to cover the vibration generating apparatus 200. The supporting member 300 may be disposed at the rear surface 100a of the passive vibration member 100 to cover an entire of the rear surface 100a of the passive vibration member 100 and the vibration generating apparatus 200. For example, the supporting member 300 may have a size which is equal to that of the passive vibration member 100. For example, the supporting member 300 may cover the rear surface 100a of the passive vibration member 100 with the vibration generating apparatus 200 and a gap space GS therebetween. For example, the supporting member 300 may cover the entire rear surface 100a of the passive vibration member 100 with the vibration generating apparatus 200 and the gap space GS therebetween. The gap space GS may be provided by the coupling member 350 disposed between the passive vibration member 100 and the supporting member 300 facing each other. The gap space GS may be referred to as an air gap, an accommodating space, a vibration space, and a sounding box, but aspects of the present disclosure are not limited thereto.

The supporting member 300 may include one or more materials of a glass material, a metal material, and a plastic material. The supporting member 300 may have a stack structure where one or more materials of a glass material, a metal material, and a plastic material are stacked.

Each of the passive vibration member 100 and the supporting member 300 may have a square shape or a rectangular shape, but aspects of the present disclosure are not limited thereto. For example, each of the passive vibration member 100 and the supporting member 300 may have a polygonal shape, a non-polygonal shape, a circular shape, or an oval shape. For example, in a case where the apparatus according to an example aspect of the present disclosure is applied to a sound apparatus or a sound bar, each of the passive vibration member 100 and the supporting member 300 may have a rectangular shape where a long-side length is twice or longer than a short-side length, but aspects of the present disclosure are not limited thereto.

The coupling member 350 may be configured to be connected between a rear edge portion (or a rear periphery portion) of the passive vibration member 100 and a front edge portion (or a front periphery portion) of the supporting member 300, and thus, the gap space GS may be provided between the passive vibration member 100 and the supporting member 300 facing each other.

The coupling member 350 according to an example aspect of the present disclosure may include an elastic material which has adhesive properties and is capable of compression and decompression. For example, the coupling member 350 may include a double-side tape, a single-sided tape, or a double-side adhesive foam pad, but aspects of the present disclosure are not limited thereto. For example, the coupling member 350 may include an elastic pad such as a rubber pad or a silicone pad, which has adhesive properties and is capable of compression and decompression. For example, the coupling member 350 may be formed by an elastomer.

As another example, the supporting member 300 may further include a sidewall portion which supports the rear edge portion (or the rear periphery portion) of the passive vibration member 100. The sidewall portion of the supporting member 300 may protrude or be bent toward the rear edge portion (or the rear periphery portion) of the passive vibration member 100 from the front edge portion (or the front periphery portion) of the supporting member 300, and thus, the gap space GS may be provided between the passive vibration member 100 and the supporting member 300. In this case, the coupling member 350 may be configured to be connected between the sidewall portion of the supporting member 300 and the rear edge portion (or the rear periphery portion) of the passive vibration member 100. Accordingly, the supporting member 300 may cover the one or more vibration generating apparatuses 200 and may support the rear surface 100a of the passive vibration member 100. For example, the supporting member 300 may cover the one or more vibration generating apparatuses 200 and may support the rear edge portion (or the rear periphery portion) of the passive vibration member 100.

As another example, the passive vibration member 100 may further include a sidewall portion which is connected to the front edge portion (or the front periphery portion) of the supporting member 300. The sidewall portion of the passive vibration member 100 may protrude or be bent toward the front edge portion (or the front periphery portion) of the supporting member 300 from the rear edge portion (or the rear periphery portion) of the passive vibration member 100, and thus, the gap space GS may be provided between the passive vibration member 100 and the supporting member 300. The passive vibration member 100 may increase in stiffness by the sidewall portion thereof. In this case, the coupling member 350 may be configured to be connected between the sidewall portion of the passive vibration member 100 and the rear edge portion (or the rear periphery portion) of the supporting member 300. Accordingly, the supporting member 300 may cover the one or more vibration generating apparatuses 200 and may support the rear surface 100a of the passive vibration member 100. For example, the supporting member 300 may cover the one or more vibration generating apparatuses 200 and may support the rear edge portion (or the rear periphery portion) of the passive vibration member 100.

The apparatus according to an example aspect of the present disclosure may further include one or more enclosures 250.

The enclosure 250 may be connected or coupled to the rear edge portion (or the rear periphery portion) of the passive vibration member 100 to individually cover the one or more vibration generating apparatuses 200. For example, the enclosure 250 may be connected or coupled to the rear surface 100a of the passive vibration member 100 by a coupling member 251. The enclosure 250 may configure a sealing space, which covers or surrounds the one or more vibration generating apparatuses 200, at the rear surface 100a of the passive vibration member 100. For example, the enclosure 250 may be a sealing member, a sealing cap, a sealing box, or a sound box, but aspects of the present disclosure are not limited thereto. The sealing space may be an air gap, a vibration space, a sound space, or a sounding box, but aspects of the present disclosure are not limited thereto.

The enclosure 250 may include one or more materials of a metal material and a nonmetal material (or a complex nonmetal material). For example, the enclosure 250 may include one or more materials of metal, plastic, and wood, but aspects of the present disclosure are not limited thereto.

The enclosure 250 according to an example aspect of the present disclosure may maintain a constant impedance component based on air acting on the passive vibration member 100 when the passive vibration member 100 or the vibration generating apparatus 200 vibrates. For example, air around the passive vibration member 100 may resist to a vibration of the passive vibration member 100 and may act as an impedance component having a resistance and a reactance component, which vary based on a frequency. Accordingly, the enclosure 250 may configure (or form) a sealing space, which surrounds the one or more vibration generating apparatuses 200, at the rear surface 100a of the passive vibration member 100, and thus, may maintain a constant impedance component (or an air impedance or an elastic impedance) acting on the passive vibration member 100 with air, thereby enhancing a sound characteristic and/or a sound pressure level characteristic of a low-pitched sound band and the sound quality of a high-pitched sound band.

A vibration apparatus and an apparatus including the vibration apparatus according to example aspects of the present disclosure are described below.

A vibration apparatus according to an aspect of the present disclosure may include a vibration generating part including a plurality of vibration parts and a connection layer between the plurality of vibration parts, and the connection layer may include a glass frit.

According to some aspects of the present disclosure, the connection layer may comprise the glass frit of 50 wt % to 70 wt %.

According to some aspects of the present disclosure, the connection layer may further comprise silver of 20 wt % or less.

According to some aspects of the present disclosure, the glass frit may comprise one material of oxides of bismuth (Bi), zinc (Zn), aluminum (Al), boron (B), and silicone (Si).

According to some aspects of the present disclosure, the connection layer may further comprise a conductive material.

According to some aspects of the present disclosure, the plurality of vibration parts may comprise a first vibration part and a second vibration part, which are vertically stacked. The connection layer may be between the first vibration part and the second vibration part.

According to some aspects of the present disclosure, each of the first vibration part and the second vibration part may comprise a first electrode layer, a second electrode layer, and a vibration layer between the first electrode layer and the second electrode layer, the vibration layer including a piezoelectric material. The connection layer may be for being electrically connected to the first electrode layer and the second electrode layer between the vibration layer of the first vibration part and the vibration layer of the second vibration part.

According to some aspects of the present disclosure, the vibration layer of the first vibration part and the vibration layer of the second vibration part may have different poling directions.

According to some aspects of the present disclosure, the first vibration part may further comprise a first auxiliary electrode layer disposed at a second surface of the vibration layer and for being electrically disconnected from the second electrode layer. The first auxiliary electrode layer may be for being electrically connected to the first electrode layer of the first vibration part through a first contact hole configured in the vibration layer of the first vibration part.

According to some aspects of the present disclosure, the second vibration part may further comprise a second auxiliary electrode layer disposed at a first surface of the vibration layer and for being electrically disconnected from the second electrode layer, and a third auxiliary electrode layer disposed at the second surface of the vibration layer and for being electrically disconnected from the first electrode layer. The second auxiliary electrode layer may be connected to the first electrode layer of the second vibration part through a second contact hole configured in the vibration layer of the second vibration part. The third auxiliary electrode layer may be connected to the second electrode layer of the second vibration part through a third contact hole configured in the vibration layer of the second vibration part.

According to some aspects of the present disclosure, the first electrode layer, the second electrode layer, and the first to third auxiliary electrode layers may comprise silver.

According to some aspects of the present disclosure, the first electrode layer, the second electrode layer, and the first to third auxiliary electrode layers may comprise a glass frit.

According to some aspects of the present disclosure, the vibration generating part may further comprise an auxiliary connection layer for being electrically disconnected from the connection layer and for being electrically connected between the first auxiliary electrode layer and the second auxiliary electrode layer.

According to some aspects of the present disclosure, the auxiliary connection layer and the connection layer may be in a same layer, or may comprise ae same material.

According to some aspects of the present disclosure, the first electrode layer of the second vibration part may be for being electrically connected to the first electrode layer of the first vibration part through the second contact hole, the second auxiliary electrode layer, the auxiliary connection layer, the first auxiliary electrode layer, and the first contact hole. The second electrode layer of the first vibration part may be for being electrically connected to the connection layer, the second electrode layer of the second vibration part, the third contact hole, and the third auxiliary electrode layer.

According to some aspects of the present disclosure, the vibration apparatus may further comprise a cover member connected to a first surface of the vibration generating part, and an adhesive layer at a second surface opposite to the first surface of the vibration generating part.

According to some aspects of the present disclosure, the vibration apparatus may further comprise a signal cable including first and second signal lines for being electrically connected to the plurality of vibration parts. The first and second signal lines may be for being electrically connected to the plurality of vibration parts, between the first surface of the vibration generating part and the cover member.

According to some aspects of the present disclosure, the vibration apparatus may further comprise a first cover member connected to a first surface of the vibration generating part, a second cover member connected to a second surface opposite to the first surface of the vibration generating part, and a signal cable including first and second signal lines for being electrically connected to the plurality of vibration parts. A portion of the signal cable may be accommodated between the first cover member and the second cover member.

According to some aspects of the present disclosure, the vibration apparatus may further comprise a signal cable including first and second signal lines for being electrically connected to the plurality of vibration parts.

According to some aspects of the present disclosure, the connection layer may be for being electrically connected between the second electrode layer of the first vibration part and the second electrode layer of the second vibration part. The first signal line may be for being electrically connected to the first electrode layer of the second vibration part and the first electrode layer of the first vibration part. The second signal line may be for being electrically connected to the second electrode layer of the first vibration part, the connection layer, and the second electrode layer of the second vibration part.

According to some aspects of the present disclosure, the vibration apparatus may further comprise a cover member connected to a first surface of the vibration generating part, and an adhesive layer at a second surface opposite to the first surface of the vibration generating part. Each of the first and second signal lines may be disposed between the second vibration part and the first surface of the vibration generating part.

According to some aspects of the present disclosure, the vibration apparatus may further comprise a first cover member connected to a first surface of the vibration generating part, and a second cover member connected to a second surface opposite to the first surface of the vibration generating part. A portion of the signal cable may be accommodated between the first cover member and the second cover member, and each of the first and second signal lines may be disposed between the second cover member and the second vibration part.

According to some aspects of the present disclosure, the vibration generating part may comprise a first auxiliary electrode layer disposed at a second surface of the vibration layer of the first vibration part to be electrically disconnected from the second electrode layer of the first vibration part and the connection layer and electrically connected to the first electrode layer of the first vibration part, a second auxiliary electrode layer for being electrically disconnected from the second electrode layer of the second vibration part and the connection layer, for being electrically connected to the first auxiliary electrode layer, and for being electrically connected to the first electrode layer of the second vibration part, and a third auxiliary electrode layer disposed at a first surface of the vibration layer of the second vibration part to be electrically disconnected from the first electrode layer of the second vibration part and electrically connected to the second electrode layer of the second vibration part. The first signal line may be for being electrically connected to the first electrode layer of the second vibration part, and the second signal line may be connected to the third auxiliary electrode layer.

According to some aspects of the present disclosure, the vibration generating part may further comprise an auxiliary connection layer for being electrically disconnected from the connection layer and for being electrically connected between the first auxiliary electrode layer and the second auxiliary electrode layer.

According to some aspects of the present disclosure, the first auxiliary electrode layer may be electrically connected to the first electrode layer of the first vibration part through a first contact hole configured in the vibration layer of the first vibration part, the second auxiliary electrode layer may be for being electrically connected to the first electrode layer of the second vibration part through a second contact hole configured in the vibration layer of the second vibration part, and the third auxiliary electrode layer may be for being electrically connected to the second electrode layer of the second vibration part through a third contact hole configured in the vibration layer of the second vibration part.

An apparatus according to an aspect of the present disclosure may include a passive vibration member and a vibration generating apparatus which is connected to the passive vibration member and configured to the passive vibration member. The vibration generating apparatus may include a vibration generating part including a plurality of vibration parts and a connection layer between the plurality of vibration parts, and the connection layer may include a glass frit.

According to some aspects of the present disclosure, the apparatus may further comprise an enclosure disposed at a rear surface of the passive vibration member.

According to some aspects of the present disclosure, the passive vibration member may comprise one or more of a vibration plate, a display panel including a pixel displaying an image, a screen panel on which an image is to be projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a vehicular means, a ceiling material of a building, an interior material of a building, a glass window of a building, an interior material of an aircraft, a glass window of an aircraft, and a mirror, and the vibration plate comprises one or more materials of metal, plastic, paper, fiber, cloth, leather, wood, rubber, glass, and carbon.

A vibration apparatus according to an embodiment of the present disclosure may include a first vibration part, a second vibration part disposed on the first vibration part, and a connection layer disposed between the first vibration part and the second vibration part and configured to attach the first vibration part and the second vibration part. The connection layer may include a glass frit.

According to some embodiments of the present disclosure, each of the first vibration part and the second vibration part may comprise a vibration layer, a first electrode layer disposed on an upper surface of the vibration layer, and a second electrode layer disposed on a lower surface of the vibration layer. The connection layer may be disposed between the first electrode layer of the first vibration part and the second electrode layer of the second vibration part.

According to some embodiments of the present disclosure, the connection layer may comprise glass frit of 50 wt % to 70 wt %.

According to some embodiments of the present disclosure, the connection layer may further comprise silver of 20 wt % or less.

According to some embodiments of the present disclosure, the vibration layer of the first vibration part and the vibration layer of the second vibration part may have different poling directions.

A vibration apparatus according to one or more example aspects of the present disclosure may be applied to or included in a vibration generating apparatus and/or a sound generating apparatus provided in an apparatus. The vibration apparatus and apparatus comprising the same according to one or more example aspects of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like. In addition, the vibration apparatus according to some example aspects of the present disclosure may be applied to or included in organic light-emitting lighting apparatuses or inorganic light-emitting lighting apparatuses. When the vibration apparatus of one or more example aspects of the present disclosure is applied to or included in lighting apparatuses, the vibration apparatus may act as a lighting device and a speaker. In addition, when the vibration apparatus according to some example aspects of the present disclosure is applied to or included in a mobile device, or the like, the vibration apparatus may be one or more of a speaker, a receiver, and a haptic device, but aspects of the present disclosure are not limited thereto.

It will be apparent to those skilled in the art that various modifications and variations can be made in the present disclosure without departing from the scope of the disclosures. Thus, it is intended that the present disclosure covers the modifications and variations of this disclosure provided they come within the scope of the appended claims and their equivalents.

What is claimed is:

1. A vibration apparatus, comprising:
a vibration generating part including a plurality of vibration parts; and
a connection layer between the plurality of vibration parts,
wherein the connection layer comprises a glass frit.

2. The vibration apparatus of claim 1, wherein the connection layer comprises the glass frit of 50 wt % to 70 wt %.

3. The vibration apparatus of claim 1, wherein the connection layer further comprises silver of 20 wt % or less.

4. The vibration apparatus of claim 1, wherein the glass frit comprises one material of oxides among bismuth (Bi), zinc (Zn), aluminum (Al), boron (B), and silicone (Si).

5. The vibration apparatus of claim 1, wherein the connection layer further comprises a conductive material.

6. The vibration apparatus of claim 1, wherein the plurality of vibration parts comprise a first vibration part and a second vibration part, which are vertically stacked, and
wherein the connection layer is between the first vibration part and the second vibration part.

7. The vibration apparatus of claim 6, wherein each of the first vibration part and the second vibration part comprises:
a first electrode layer;
a second electrode layer; and
a vibration layer between the first electrode layer and the second electrode layer, and the vibration layer including a piezoelectric material, and
wherein the connection layer is for being electrically connected to the first electrode layer and the second electrode layer between the vibration layer of the first vibration part and the vibration layer of the second vibration part.

8. The vibration apparatus of claim 7, wherein the vibration layer of the first vibration part and the vibration layer of the second vibration part have different poling directions.

9. The vibration apparatus of claim 7, wherein the first vibration part further comprises a first auxiliary electrode layer disposed at a second surface of the vibration layer and for being electrically disconnected from the second electrode layer, and
wherein the first auxiliary electrode layer is for being electrically connected to the first electrode layer of the first vibration part through a first contact hole configured in the vibration layer of the first vibration part.

10. The vibration apparatus of claim 9, wherein the second vibration part further comprises:
a second auxiliary electrode layer disposed at a first surface of the vibration layer and for being electrically disconnected from the second electrode layer; and
a third auxiliary electrode layer disposed at the second surface of the vibration layer and for being electrically disconnected from the first electrode layer,
wherein the second auxiliary electrode layer is connected to the first electrode layer of the second vibration part through a second contact hole configured in the vibration layer of the second vibration part, and
wherein the third auxiliary electrode layer is connected to the second electrode layer of the second vibration part through a third contact hole configured in the vibration layer of the second vibration part.

11. The vibration apparatus of claim 10, wherein the first electrode layer, the second electrode layer, and the first to third auxiliary electrode layers comprise silver.

12. The vibration apparatus of claim 11, wherein the first electrode layer, the second electrode layer, and the first to third auxiliary electrode layers comprise a glass frit.

13. The vibration apparatus of claim 10, wherein the vibration generating part further comprises an auxiliary connection layer for being electrically disconnected from the connection layer and for being electrically connected between the first auxiliary electrode layer and the second auxiliary electrode layer.

14. The vibration apparatus of claim 13, wherein the auxiliary connection layer and the connection layer are in a same layer, or comprise a same material.

15. The vibration apparatus of claim 13, wherein the first electrode layer of the second vibration part is for being electrically connected to the first electrode layer of the first vibration part through the second contact hole, the second auxiliary electrode layer, the auxiliary connection layer, the first auxiliary electrode layer, and the first contact hole, and
wherein the second electrode layer of the first vibration part is for being electrically connected to the connection layer, the second electrode layer of the second vibration part, the third contact hole, and the third auxiliary electrode layer.

16. The vibration apparatus of claim 1, further comprises:
a cover member connected to a first surface of the vibration generating part; and
an adhesive layer at a second surface opposite to the first surface of the vibration generating part.

17. The vibration apparatus of claim 16, further comprising a signal cable including first and second signal lines for being electrically connected to the plurality of vibration parts,
wherein the first and second signal lines are for being electrically connected to the plurality of vibration parts, between the first surface of the vibration generating part and the cover member.

18. The vibration apparatus of claim 1, further comprising:
a first cover member connected to a first surface of the vibration generating part;
a second cover member connected to a second surface opposite to the first surface of the vibration generating part; and
a signal cable including first and second signal lines for being electrically connected to the plurality of vibration parts,
wherein a portion of the signal cable is accommodated between the first cover member and the second cover member.

19. The vibration apparatus of claim 7, further comprising a signal cable including first and second signal lines for being electrically connected to the plurality of vibration parts.

20. The vibration apparatus of claim 19, wherein the connection layer is for being electrically connected between the second electrode layer of the first vibration part and the second electrode layer of the second vibration part,
wherein the first signal line is for being electrically connected to the first electrode layer of the second vibration part and the first electrode layer of the first vibration part, and
wherein the second signal line is for being electrically connected to the second electrode layer of the first vibration part, the connection layer, and the second electrode layer of the second vibration part.

21. The vibration apparatus of claim 20, further comprising:
a cover member connected to a first surface of the vibration generating part; and
an adhesive layer at a second surface opposite to the first surface of the vibration generating part,
wherein each of the first and second signal lines is disposed between the second vibration part and the first surface of the vibration generating part.

22. The vibration apparatus of claim 20, further comprising:
a first cover member connected to a first surface of the vibration generating part; and
a second cover member connected to a second surface opposite to the first surface of the vibration generating part,
wherein a portion of the signal cable is accommodated between the first cover member and the second cover member, and
wherein each of the first and second signal lines is disposed between the second cover member and the second vibration part.

23. The vibration apparatus of claim 20, wherein the vibration generating part comprises:
a first auxiliary electrode layer disposed at a second surface of the vibration layer of the first vibration part to be electrically disconnected from the second electrode layer of the first vibration part and the connection layer and electrically connected to the first electrode layer of the first vibration part;
a second auxiliary electrode layer for being electrically disconnected from the second electrode layer of the second vibration part and the connection layer, for being electrically connected to the first auxiliary electrode layer, and for being electrically connected to the first electrode layer of the second vibration part; and
a third auxiliary electrode layer disposed at a first surface of the vibration layer of the second vibration part to be electrically disconnected from the first electrode layer of the second vibration part and electrically connected to the second electrode layer of the second vibration part,
wherein the first signal line is for being electrically connected to the first electrode layer of the second vibration part, and
wherein the second signal line is connected to the third auxiliary electrode layer.

24. The vibration apparatus of claim 23, wherein the vibration generating part further comprises an auxiliary connection layer for being electrically disconnected from the connection layer and for being electrically connected between the first auxiliary electrode layer and the second auxiliary electrode layer.

25. The vibration apparatus of claim 23, wherein the first auxiliary electrode layer is for being electrically connected to the first electrode layer of the first vibration part through a first contact hole configured in the vibration layer of the first vibration part,
wherein the second auxiliary electrode layer is for being electrically connected to the first electrode layer of the second vibration part through a second contact hole configured in the vibration layer of the second vibration part, and
wherein the third auxiliary electrode layer is for being electrically connected to the second electrode layer of the second vibration part through a third contact hole configured in the vibration layer of the second vibration part.

26. An apparatus, comprising:
a passive vibration member; and
a vibration generating apparatus connected to the passive vibration member and configured to vibrate the passive vibration member,
wherein the vibration generating apparatus comprises the vibration apparatus of claim 1.

27. The apparatus of claim 26, further comprising an enclosure disposed at a rear surface of the passive vibration member.

28. The apparatus of claim 26, wherein the passive vibration member comprises one or more of a vibration plate, a display panel including a pixel displaying an image, a screen panel on which an image is to be projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a vehicular means, a ceiling material of a building, an interior material of a building, a glass window of a building, an interior material of an aircraft, a glass window of an aircraft, and a mirror, and
wherein the vibration plate comprises one or more materials of metal, plastic, paper, fiber, cloth, leather, wood, rubber, glass, and carbon.
